(19) United States
(12) Patent Application Publication
(10) Pub. No.: US 2006/0234084 A1
(43) Pub. Date: Oct. 19, 2006

(54) OLED device with improved luminescent layer

(75) Inventors: Lelia Cosimbescu, Rochester, NY (US); Douglas R. Robello, Webster, NY (US); Jeri L. Mount, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/109,612

(22) Filed: Apr. 19, 2005

(51) Int. Cl. H01L 51/54; H05B 33/14

(52) U.S. Cl. 428/690; 428/917; 313/504

(57) ABSTRACT

A light-emitting layer contains a host and a light-emitting anthracene compound bearing a 10-ethynyl moiety as the predominant light-emitting compound in the layer. Embodiments of the invention provide desirable luminance efficiency, hue and/or operational stability.

### FIELD OF THE INVENTION

This invention relates to an OLED device containing an emitting layer comprising a host and a light-emitting anthracene compound bearing a 10-ethynyl moiety as the predominant light-emitting compound in the layer.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, 30, 322-334, (1969); and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often greater than 100V.

More recent organic EL devices include an organic EL element consisting of extremely thin layers (e.g., less than 1.0 μm) between the anode and the cathode. Herein, the term “organic EL element” encompasses the layers between the anode and cathode. Reducing the thickness lowered the resistance of the organic layer and has enabled devices that operate at much lower voltage. In a basic two-layer EL device structure, described first in U.S. Pat. No. 4,356,429, one organic layer of the EL element adjacent to the anode is specifically chosen to transport holes, and therefore, it is referred to as the hole-transporting layer, and the other organic layer is specifically chosen to transport electrons, and is referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by Tang et al (J. Applied Physics, 65, Pages 3610-3616, (1989)). The light-emitting layer commonly consists of a host material doped with a guest material, also known as a dopant. Still further, there has been proposed in U.S. Pat. No. 4,769,292 a four-layer EL element comprising a hole-injecting layer (HIL), a hole-transporting layer (HTL), a light-emitting layer (LEL) and an electron transport/injection layer (ETL). These structures have resulted in improved device efficiency.

Since these early inventions, further improvements in device materials have resulted in improved performance in attributes such as color, stability, luminance efficiency and manufacturability, e.g., as disclosed in U.S. Pat. No. 5,061,569, U.S. Pat. No. 5,409,783, U.S. Pat. No. 5,554,450, U.S. Pat. No. 5,593,788, U.S. Pat. No. 5,683,823, U.S. Pat. No. 5,908,581, U.S. Pat. No. 5,928,802, U.S. Pat. No. 6,020,078, and U.S. Pat. No. 6,208,077, amongst others.

Notwithstanding these developments, there are continuing needs for organic EL device components, such as light-emitting materials, sometimes referred to as dopants, that will provide long lifetimes and acceptable luminance efficiencies and good color. In particular, there is a need to be able to adjust the emission wavelength of the light-emitting material for various applications. For example, in addition to the need for blue, green, and red light-emitting materials there is a need for blue-green, yellow and orange light-emitting materials in order to formulate white-light emitting electroluminescent devices. For example, a device can emit white light by emitting a combination of colors, such as blue-green light and red light or a combination of blue light and orange light.

White EL devices can be used with color filters in full-color display devices. They can also be used with color filters in other multicolor or functional-color display devices. White EL devices for use in such display devices are easy to manufacture, and they produce reliable white light in each pixel of the displays. Although the OLEDs are referred to as white they can appear white or off-white, the CIE coordinates of the light emitted by the OLED are less important than the requirement that the spectral components passed by each of the color filters be present with sufficient intensity in that light. The devices must also have good stability in long-term operation. That is, as the devices are operated for extended periods of time, the luminance of the devices should decrease as little as possible. There is a need for new materials that improve the operational stability of devices.

Certain ethynyl materials have been reported to have interesting spectral properties, for example, see S. Akiyama, K. Nakashima, S. Nakatsuji, and M. Nakagawa, Dyes and Pigments, 13, 117, 1990. However, with a few exceptions, they have not found widespread use in EL devices. In one example, G. Yu, Y. Liu, X. Zhan, H. Li, M. Yang, D. Zhu, Thin Solid Films, 363 126 (2000), have reported emission from a series of aryl-substituted double-bonded polyacetylenes, poly(phenylacetylene), poly(p-ethynylphenylacetylene), poly(p-phenylethynylphenylacetylene)), and poly[p-(2-thiophenylethynyl)phenylacetylene]. Single layer light-emitting diodes using these materials as an emissive layer were fabricated. T. Shinji, A. Goro, T. Akira, and I. Jun, JP 2000021571, describe materials to be included in a light-emitting layer. These materials may include a compound that has two acetylenic groups. In another example, Ishida Tsutomo, Shiozaki Hiroyoshi; OgisoAkira are reporting an optical recording medium containing acetylenic compounds in JP2004082439. An acetylenic compound is reported as an emitting material in an organic laser device in US2003161368. An acetylenic compound is reported as a co-host to be used with a separate emitting dopant for improved stability in US2004076853. Heller and Rio report alkynyl compounds as organic scintillators, in Bull. Soc. Chim. Fr., 1707, 1963. Notwithstanding these peripherally related developments, there is a continuing need in OLED devices for alternative emitting materials, that exhibit improved properties such as luminance efficiency, hue or stability.

### SUMMARY OF THE INVENTION

The invention provides an OLED device comprising a light-emitting layer containing a host and a light-emitting anthracene compound bearing a 10-ethynyl moiety as the predominant light-emitting compound in the layer. The invention also provides a display including such a device and a method of imaging using such a device. The invention provides alternative emitting materials that exhibit good luminance efficiency, operational stability and a range of hues: from a short blue (λmax=400−450 nm) to a blue-green hue (λmax=450−490 nm). Such a device may exhibit desirable luminance efficiency, color hue and/or stability.

### BRIEF DESCRIPTION OF THE DRAWING

FIG. 1 is a schematic multilayer showing the layer arrangement of typical OLED devices of the invention.

### DETAILED DESCRIPTION OF THE INVENTION

The invention is generally as described above. An OLED device of the invention is a multilayer electroluminescent device comprising a cathode, an anode, charge-injecting layers (if necessary), charge-transporting layers, and a light-emitting layer (LEL) comprising a host and at least one ethynyl anthracene light-emitting dopant.

Compounds useful in the invention are suitably represented by Formula (1): 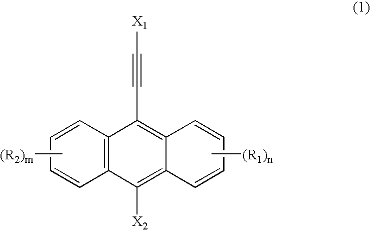
wherein X₁ and X₂ are independently selected from hydrogen, alkyl, silyl groups and aryl groups and each R₁ and R₂ is an individually selected substituent where each of m and n is 0 to 4, and desirably both m and n are 0.

X₁ and X₂ are individually selected from hydrogen, alkyl groups, silyl groups, aromatic groups of 6-50 nuclear carbon atoms, aromatic heterocyclic groups of 5-50 nuclear carbon atoms, arylalkyl groups of 6-50 carbon atoms, aryloxy groups of 5-50 nuclear carbon atoms, arylthio groups of 5-50 nuclear carbon atoms, all of which may be substituted or unsubstituted. Suitably in Formula (1), X₁ and X₂ are independently selected from trimethylsilyl, diphenylmethyl silyl, triphenyl silyl, and substituted or unsubstituted phenyl, tolyl, naphthyl, terphenyl, mesityl, biphenyl, phenanthryl, pyrenyl, fluorenyl, fluoranthryl, pyrrolyl, pyridinyl, indolyl, alkoxyl, phenyloxyl, benzyl, thiophenyl, benzothiophenyl, methyl, and t-butyl groups. In a preferred embodiment, X₁ is either a fused ring group (two or more fused rings to form an aromatic group) or a para-substituted phenyl group.

Typically, X₁ and X₂ are independently selected from phenyl, 4-t-butyl-phenyl, 1-naphthyl, 2-naphthyl, 4-biphenyl, and mesityl group, provided that X₁ and X₂ are not both unsubstituted phenyl and that X₁ is not phenyl when X₂ is methyl.

R₁ and R₂ are independently selected from hydrogen or a substituent group. The substituent is selected from substituted or unsubstituted groups such as a silyl group, an aromatic group of 6-50 nuclear carbon atoms, an aromatic heterocyclic group of 5-50 nuclear carbon atoms, an alkyl group of 1-50 carbon atoms, an alkoxy group of 1-50 carbon atoms, an arylalkyl group of 6-50 carbon atoms, an aryloxy group of 5-50 nuclear carbon atoms, an arylthio group of 5-50 nuclear carbon atoms, a alkoxycarbonyl group of 1-50 carbon atoms, carboxy group, chloro, fluoro, cyano group, nitro group, or hydroxy group. Usefully, R₁ and R₂ are hydrogen, methyl, ethyl, t-butyl, trimethylsilyl, phenyl, tolyl, 2-naphthyl, biphenyl, methoxy, phenoxy, thiophenyl, or mesityl groups. Typically, R₁ and R₂ are hydrogen.

Suitably the light-emitting material of Formula (1) is present in an amount less than 10 vol % by volume of the layer, preferably less than 5 vol. % of the emitting layer, and typically in the range of 0.5 to 3 vol. %.

Embodiments of the Formula (1) materials useful in the invention can provide a range of hues, good stability, or good luminance, or a combination thereof. Embodiments of the light-emitting materials especially useful in the invention provide an emitted light having a short blue (λmax=400−430 nm). or a blue-green hue (λmax=450−490 nm). In another embodiment, Formula (1) materials useful in the invention are used in an electroluminescent device that emits white light.

Illustrative examples of compounds of Formula (1) useful in the present invention include the compounds listed below.

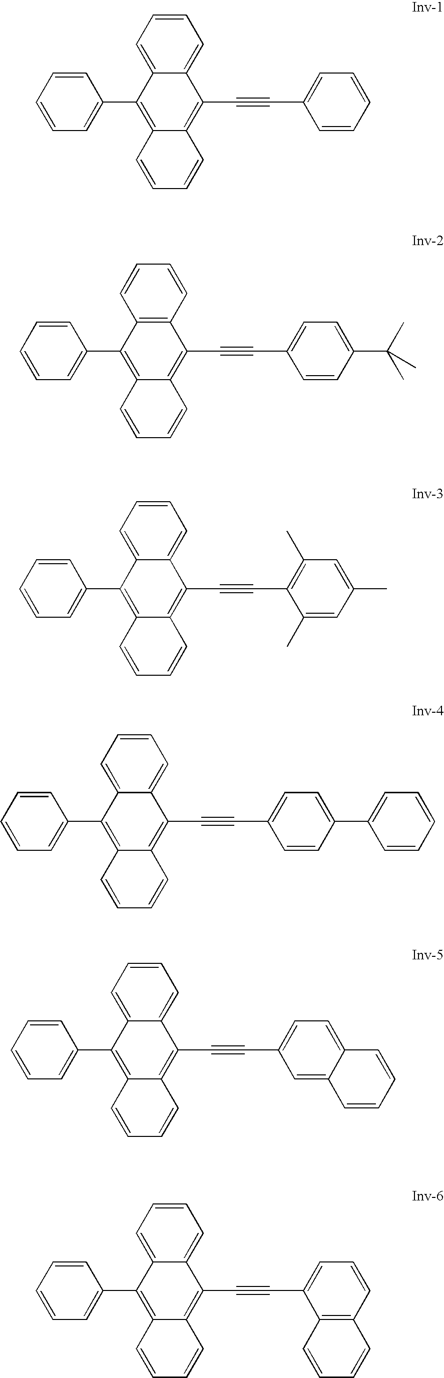

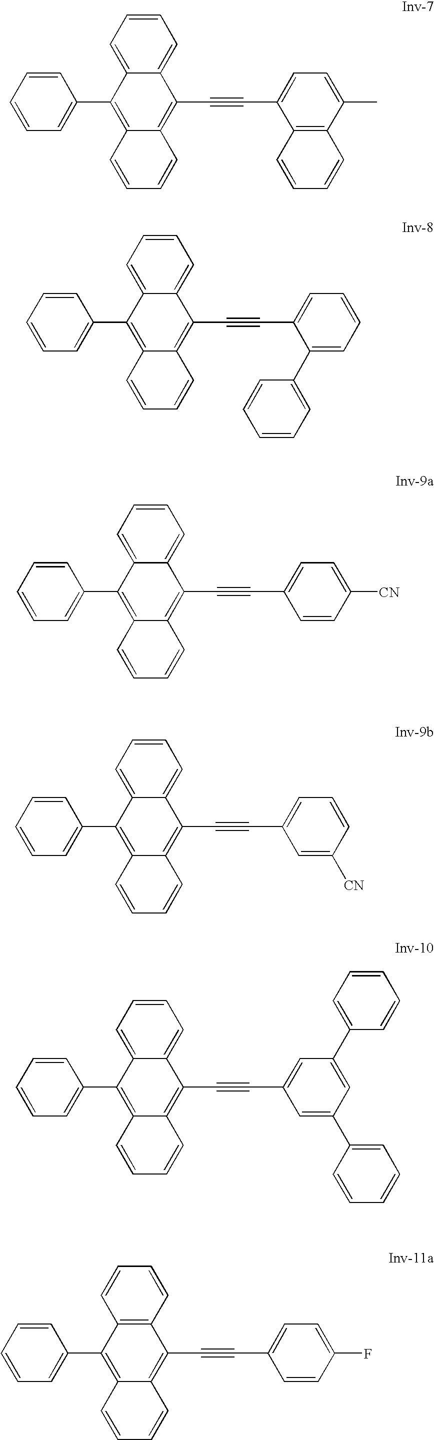

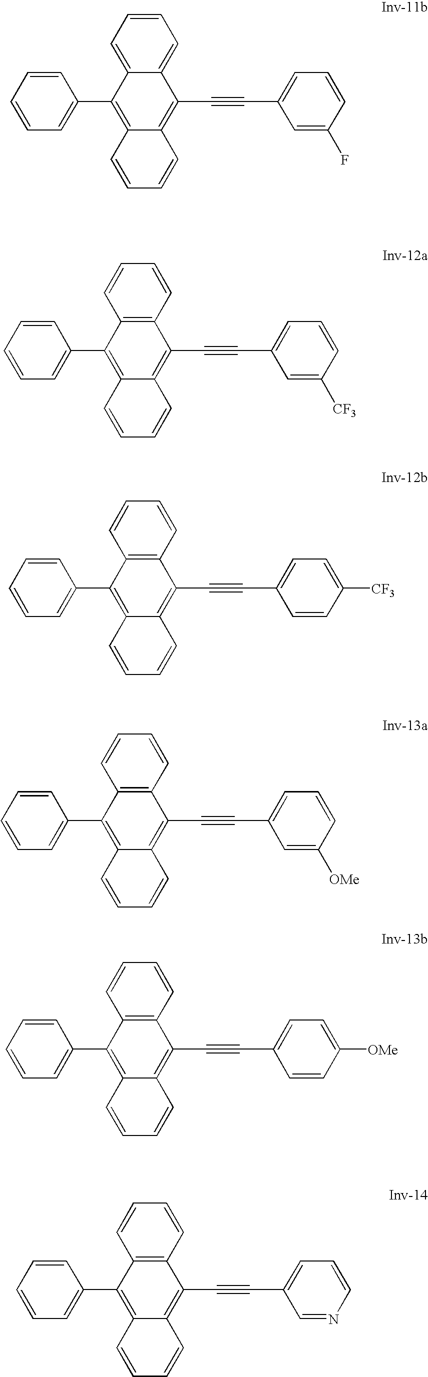

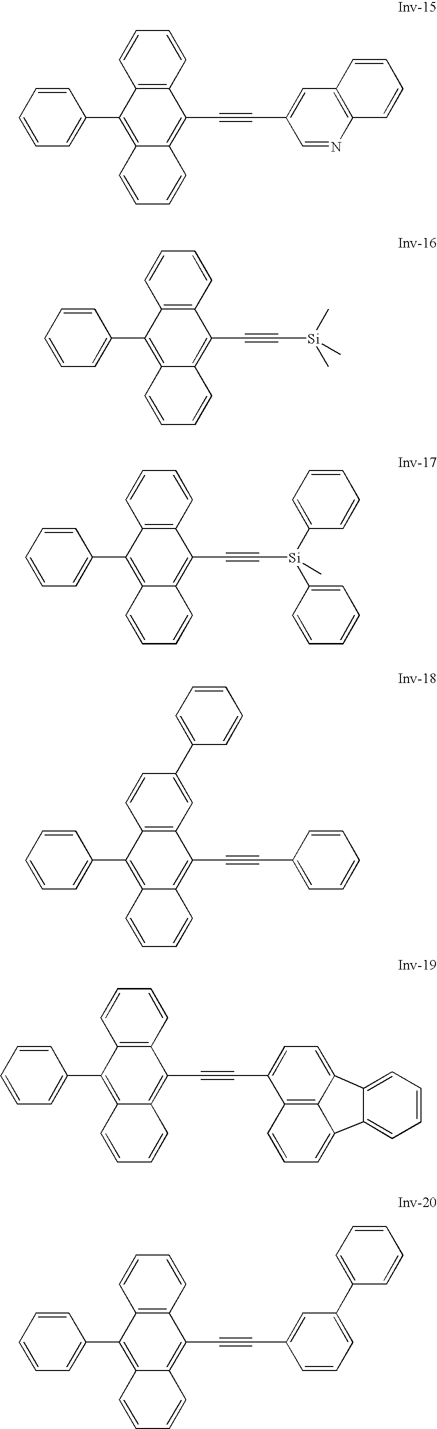

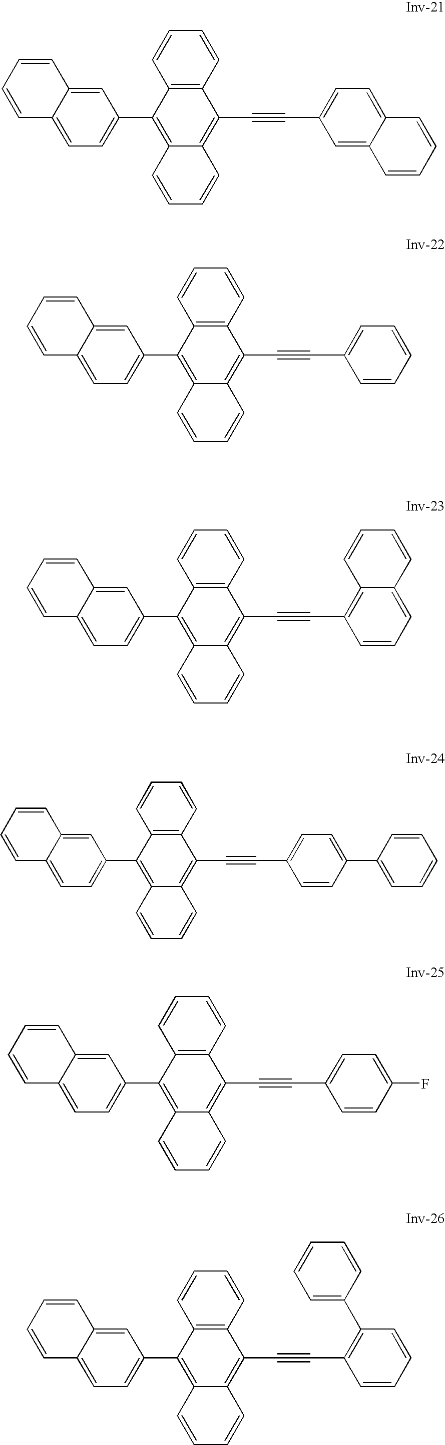

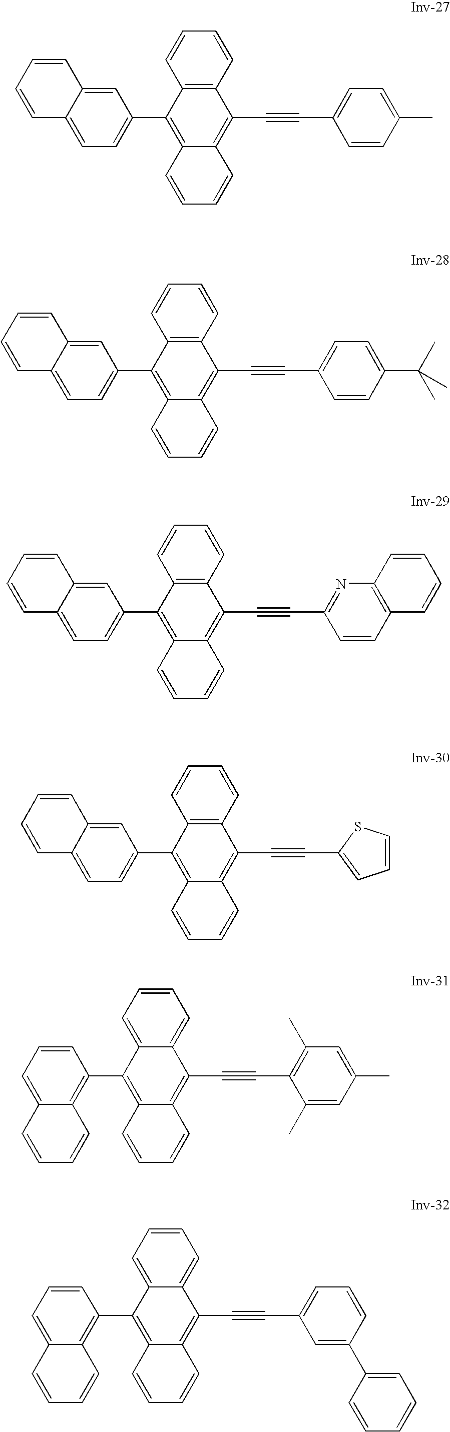

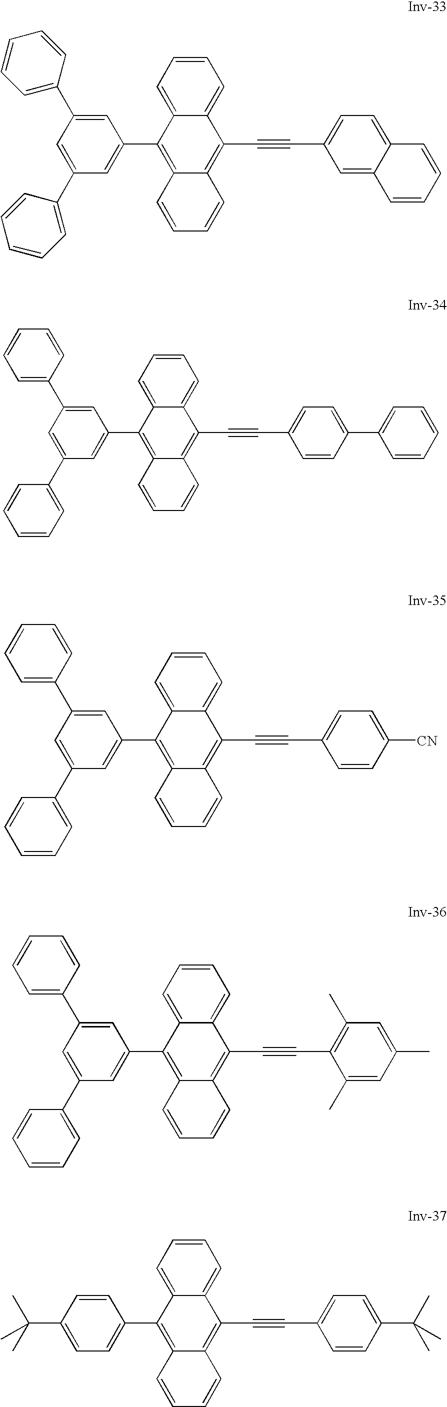

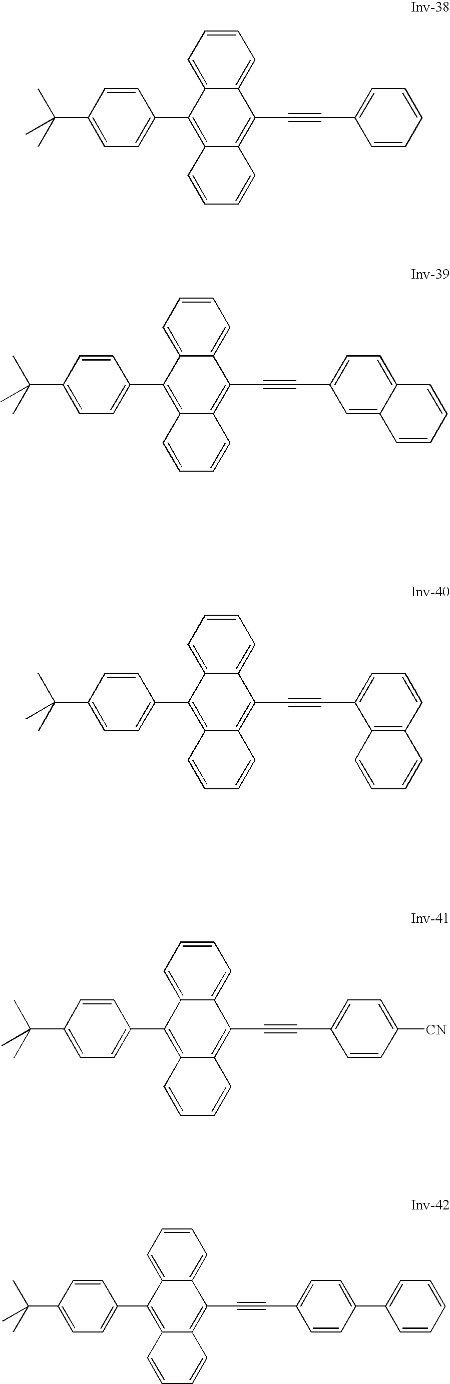

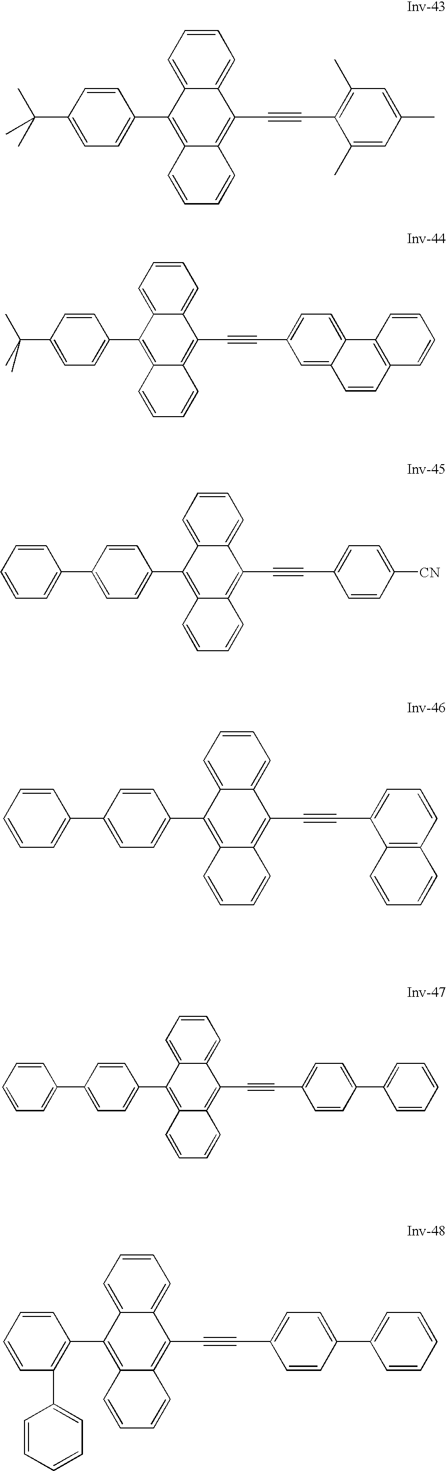

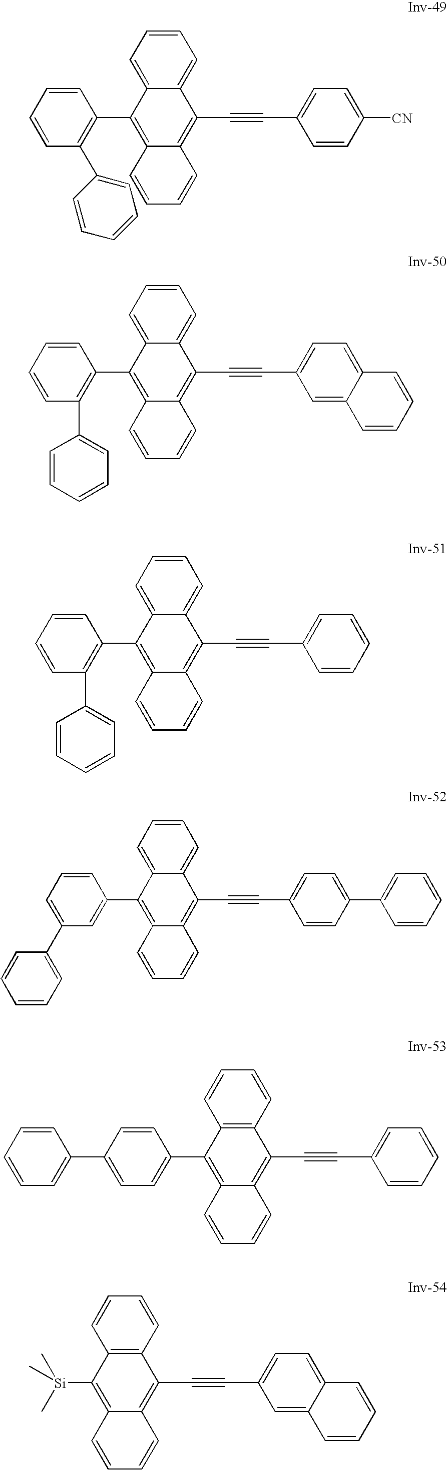

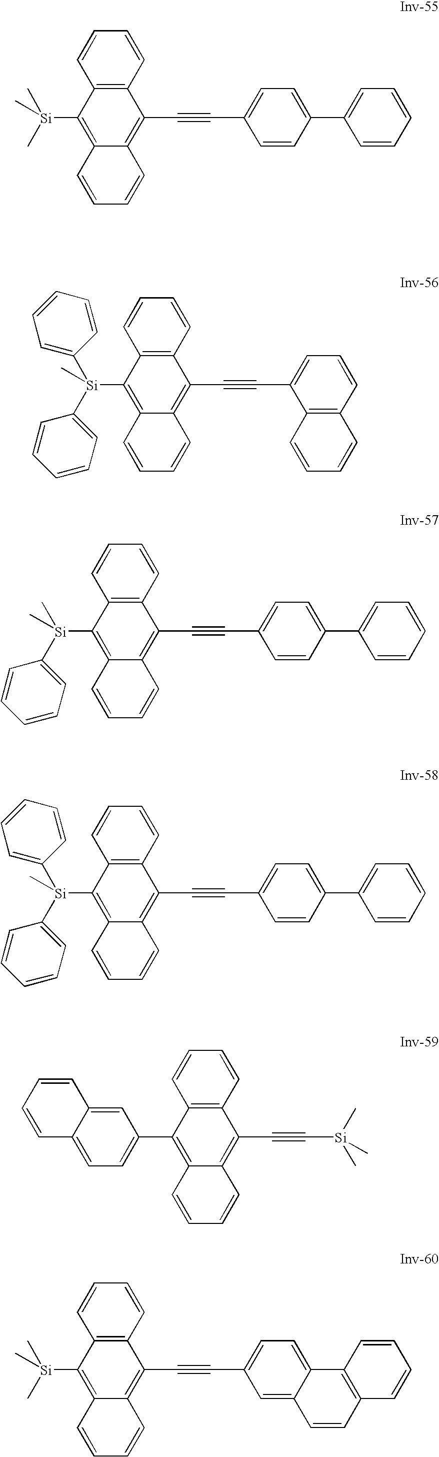

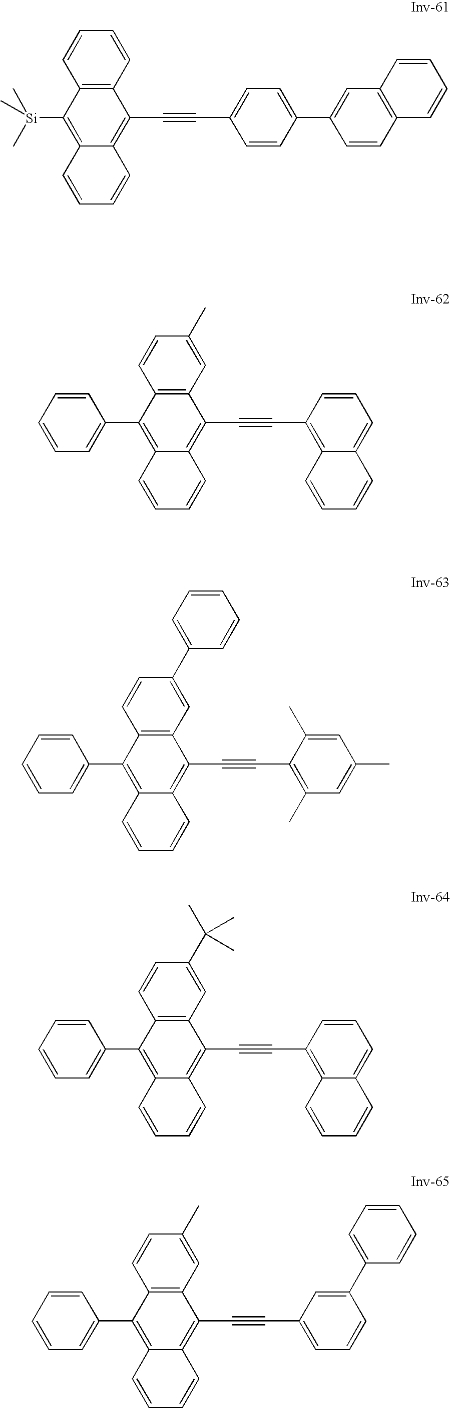

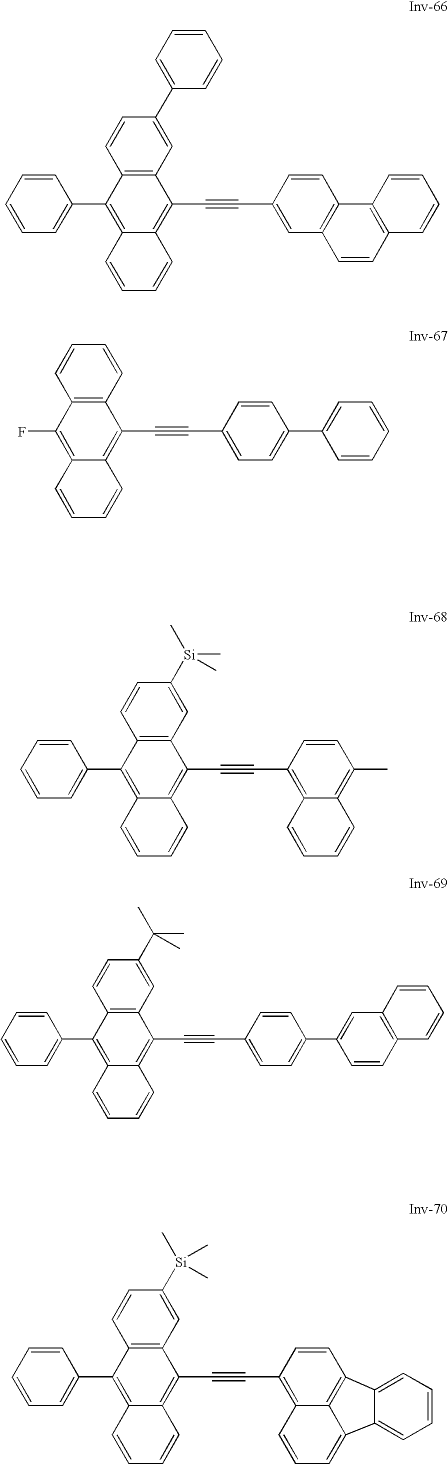

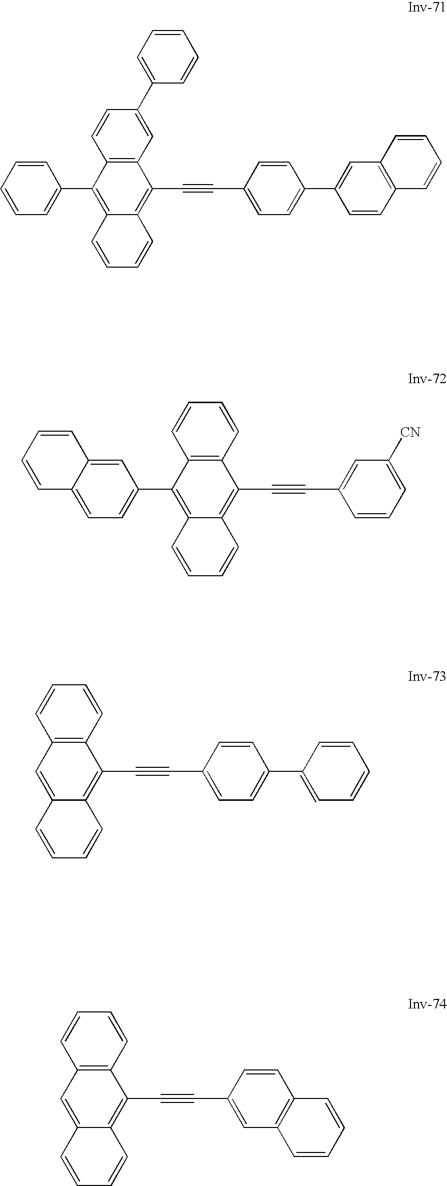

Desirable hosts include those based on an anthracene compound. In one desirable embodiment the host is represented by Formula (2).

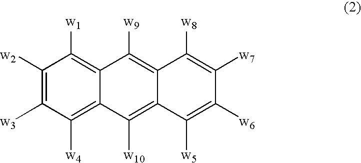

In Formula (2), W₁-W₁₀ independently represent hydrogen or an independently selected substituent, provided that two adjacent substituents can combine to form a ring. In one suitable embodiment, W₉ and W₁₀ independently represent naphthyl groups. In another desirable embodiment, W₉ and W₁₀ represent a naphthyl group and a biphenyl group.

Particular examples of hosts are 9,10-di-(2-naphthyl)anthracene, 2-t-butyl-9,10-di-(2-naphthyl)anthracene, 9-(4-biphenyl)-10-(2-naphthyl)anthracene and 9-(4-biphenyl)-10-(1-naphthyl)anthracene. Usefully, the host is selected such that the host absorbs light at a shorter wavelength than the dopant and the emission spectrum of the host overlaps with the absorption spectrum of the dopant.

Embodiments of the invention provide not only good luminance efficiency but also a blue or blue-green hue as evidenced by the location and shape of the emission curve of the emitted light. Embodiments of the invention can provide improved operational stability, either when used as the light-emitting material or in combination with another light-emitting material. Embodiments of the invention can be used in a host or a combination of two hosts to obtain a particular property enhancement (i.e. stability).

Unless otherwise specifically stated, use of the term “substituted” or “substituent” means any group or atom other than hydrogen. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; silicon; nitro; hydroxyl; cyano; carboxyl; or groups which may be further substituted, such as alkyl, including straight or branched chain or cyclic alkyl, such as methyl, trifluoromethyl, ethyl, t-butyl; alkenyl, such as ethylene, 2-butene; alkoxy, such as methoxy, ethoxy, propoxy, butoxy, 2-methoxyethoxy, sec-butoxy; aryl such as phenyl, 4-t-butylphenyl, 2,4,6-trimethylphenyl, naphthyl, biphenyl; aryloxy, such as phenoxy, 2-methylphenoxy, alpha- or beta-naphthyloxy, and 4-tolyloxy; amine, phosphate, phosphite, a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron, such as pyridyl, thienyl, furyl, azolyl, thiazolyl, oxazolyl, imidazolyl, pyrazolyl, pyrazinyl, pyrimidinyl, pyrolidinonyl, quinolinyl, and isoquinolinyl, 2-furyl, 2-thienyl, 2-benzimidazolyloxy or 2-benzothiazolyl, quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain the desired desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

General Device Architecture

The present invention can be employed in many EL device configurations using small molecule materials, oligomeric materials, polymeric materials, or combinations thereof. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers may be employed as more fully described hereafter.

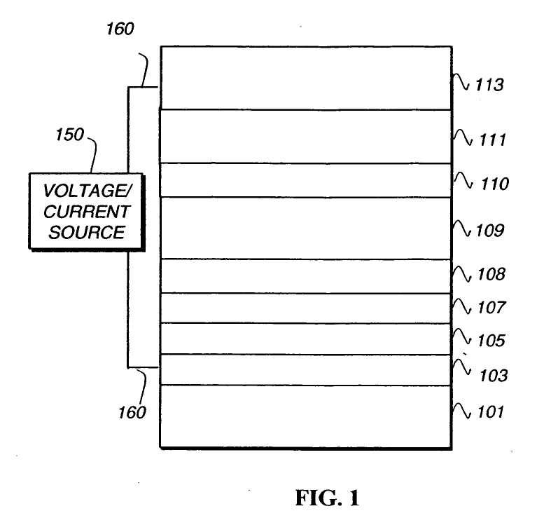

A typical structure according to the present invention and especially useful for a small molecule device, is shown in FIG. 1 and is comprised of a substrate 101, an anode 103, a hole-injecting layer 105, a hole-transporting layer 107, a light-emitting layer 109, an electron-transporting layer 111, and a cathode 113. These layers are described in detail below. Note that the substrate 101 may alternatively be located adjacent to the cathode 113, or the substrate 101 may actually constitute the anode 103 or cathode 113. The organic layers between the anode 103 and cathode 113 are conveniently referred to as the organic EL element. Also, the total combined thickness of the organic layers is desirably less than 500 nm. If the device includes phosphorescent material, a hole-blocking layer, located between the light-emitting layer and the electron-transporting layer, may be present.

The anode 103 and cathode 113 of the OLED are connected to a voltage/current source 150 through electrical conductors 160. The OLED is operated by applying a potential between the anode 103 and cathode 113 such that the anode 103 is at a more positive potential than the cathode 113. Holes are injected into the organic EL element from the anode 103 and electrons are injected into the organic EL element at the cathode 113. Enhanced device stability can sometimes be achieved when the OLED is operated in an AC mode where, for some time period in the AC cycle, the potential bias is reversed and no current flows. An example of an AC driven OLED is described in U.S. Pat. No. 5,552,678.

Substrate The OLED device of this invention is typically provided over a supporting substrate 101 where either the cathode 113 or anode 103 can be in contact with the substrate. The electrode in contact with the substrate 101 is conveniently referred to as the bottom electrode. Conventionally, the bottom electrode is the anode 103, but this invention is not limited to that configuration. The substrate 101 can either be light transmissive or opaque, depending on the intended direction of light emission. The light transmissive property is desirable for viewing the EL emission through the substrate 101. Transparent glass or plastic is commonly employed in such cases. The substrate 101 can be a complex structure comprising multiple layers of materials. This is typically the case for active matrix substrates wherein TFTs are provided below the OLED layers. It is still necessary that the substrate 101, at least in the emissive pixelated areas, be comprised of largely transparent materials such as glass or polymers. For applications where the EL emission is viewed through the top electrode, the transmissive characteristic of the bottom support is immaterial, and therefore the substrate can be light transmissive, light absorbing or light reflective. Substrates for use in this case include, but are not limited to, glass, plastic, semiconductor materials such as silicon, ceramics, and circuit board materials. Again, the substrate 101 can be a complex structure comprising multiple layers of materials such as found in active matrix TFT designs. It is necessary to provide in these device configurations a light-transparent top electrode.

Anode

When the desired electroluminescent light emission (EL) is viewed through the anode, the anode 103 should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode 103. For applications where EL emission is viewed only through the cathode 113, the transmissive characteristics of the anode 103 are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize short circuits or enhance reflectivity.

Cathode

When light emission is viewed solely through the anode 103, the cathode 113 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising the cathode and a thin electron-injection layer (EIL) in contact with an organic layer (e.g., an electron transporting layer (ETL)), the cathode being capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. An ETL material doped with an alkali metal, for example, Li-doped Alq, is another example of a useful EIL. Other useful cathode material sets include, but are not limited to, those disclosed in U.S. Pat. Nos. 5,059,861, 5,059,862, and 6,140,763.

When light emission is viewed through the cathode, the cathode 113 must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,3936. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Hole-Injecting Layer (HIL)

A hole-injecting layer 105 may be provided between anode 103 and hole-transporting layer 107. The hole-injecting layer can serve to improve the film formation property of subsequent organic layers and to facilitate injection of holes into the hole-transporting layer 107. Suitable materials for use in the hole-injecting layer 105 include, but are not limited to, porphyrinic compounds as described in U.S. Pat. No. 4,720,432, plasma-deposited fluorocarbon polymers as described in U.S. Pat. No. 6,208,075, and some aromatic amines, for example, MTDATA (4,4′,4″-tris[(3-methylphenyl)phenylamino]triphenylamine). Alternative hole-injecting materials reportedly useful in organic EL devices are described in EP 0 891 121 A1 and EP 1 029 909 A1. A hole-injection layer is conveniently used in the present invention, and is desirably a plasma-deposited fluorocarbon polymer. The thickness of a hole-injection layer containing a plasma-deposited fluorocarbon polymer can be in the range of 0.2 nm to 15 nm and suitably in the range of 0.3 to 1.5 nm.

Hole-Transporting Layer (HTL)

While not always necessary, it is often useful to include a hole-transporting layer in an OLED device. The hole-transporting layer 107 of the organic EL device contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more preferred class of aromatic tertiary amines is those which include at least two aromatic tertiary amine moieties as described in U.S. Pat. No. 4,720,432 and U.S. Pat. No. 5,061,569. Such compounds include those represented by structural formula (A). 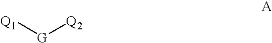
wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural formula (A) and containing two triarylamine moieties is represented by structural formula (B): 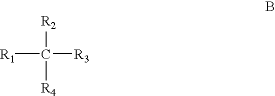
where
R₁ and R₂ each independently represents a hydrogen atom, an aryl group, or an alkyl group or R₁ and R₂ together represent the atoms completing a cycloalkyl group; and
R₃ and R₄ each independently represents an aryl group, which is in turn substituted with a diaryl substituted amino group, as indicated by structural formula (C): 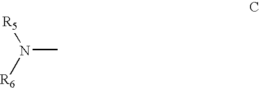
   wherein R₅ and R₆ are independently selected aryl groups. In one embodiment, at least one of R₅ or R₆ contains a polycyclic fused ring structure, e.g., a naphthalene.

Another class of aromatic tertiary amines is the tetraaryldiamines. Desirable tetraaryldiamines include two diarylamino groups, such as indicated by formula (C), linked through an arylene group. Useful tetraaryldiamines include those represented by formula (D). 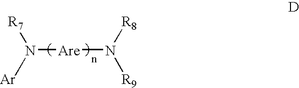
wherein
each Are is an independently selected arylene group, such as a phenylene or anthracene moiety,
n is an integer of from 1 to 4, and
Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural formulae (A), (B), (C), (D), can each in turn be substituted. Typical substituents include alkyl groups, alkoxy groups, aryl groups, aryloxy groups, and halide such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single tertiary amine compound or a mixture of such compounds. Specifically, one may employ a triarylamine, such as a triarylamine satisfying the formula (B), in combination with a tetraaryldiamine, such as indicated by formula (D). Illustrative of useful aromatic tertiary amines are the following:
1,1-Bis(4-di-p-tolylaminophenyl)cyclohexane (TAPC)
1,1-Bis(4-di-p-tolylaminophenyl)-4-methylcyclohexane
1,1-Bis(4-di-p-tolylaminophenyl)-4-phenylcyclohexane
1,1-Bis(4-di-p-tolylaminophenyl)-3-phenylpropane (TAPPP)
N,N,N′,N′-tetraphenyl-4,4′″-diamino-1,1′:4′,1″:4″,1″′-quaterphenyl
Bis(4-dimethylamino-2-methylphenyl)phenylmethane
1,4-bis[2-[4-[N,N-di(p-toly)amino]phenyl]vinyl]benzene (BDTAPVB)
N,N,N′,N′-Tetra-p-tolyl-4,4′-diaminobiphenyl (TTB)
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl (NPB)
4,4′-Bis[N-(1-naphthyl)-N-(2-naphthyl)amino]biphenyl (TNB)
4,4′-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4′-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis {N-phenyl-N-[4-(1-naphthyl)-phenyl]amino}biphenyl
2,6-Bis[N,N-di(2-naphthyl)amino]fluorene
4,4′,4″-tris[(3-methylphenyl)phenylamino]triphenylamine (MTDATA)
4,4′-Bis[N-(3-methylphenyl)-N-phenylamino]biphenyl (TPD)

Another class of useful hole-transporting materials includes polycyclic aromatic compounds as described in EP 1 009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS. It is also possible for the hole-transporting layer to comprise two or more sublayers of differing compositions, the composition of each sublayer being as described above. The thickness of the hole-transporting layer can be between 10 and about 500 nm and suitably between 50 and 300 nm.

Light-Emitting Layer (LEL)

In addition to the light-emitting materials of this invention, additional light emitting materials may be used in the EL device, including other fluorescent materials. Other fluorescent materials may be used in the same layer as the inventive material, in adjacent layers, in adjacent pixels, or any combination.

As more fully described in U.S. Pat. Nos. 4,769,292 and 5,935,721, the light-emitting layer (LEL) of the organic EL element includes a luminescent material where electroluminescence is produced as a result of electron-hole pair recombination. The light-emitting layer can be comprised of a single material, but more commonly consists of a host material doped with a guest emitting material or materials where light emission comes primarily from the emitting materials and can be of any color. The host materials in the light-emitting layer can be an electron-transporting material, as defined below, a hole-transporting material, as defined above, or another material or combination of materials that support hole-electron recombination. Fluorescent emitting materials are typically incorporated at 0.01 to 10% by weight of the host material.

The host and emitting materials can be small non-polymeric molecules or polymeric materials such as polyfluorenes and polyvinylarylenes (e.g., poly(p-phenylenevinylene), PPV). In the case of polymers, small-molecule emitting materials can be molecularly dispersed into a polymeric host, or the emitting materials can be added by copolymerizing a minor constituent into a host polymer. Host materials may be mixed together in order to improve film formation, electrical properties, light emission efficiency, operating lifetime, or manufacturability. The host may comprise a material that has good hole-transporting properties and a material that has good electron-transporting properties.

An important relationship for choosing a fluorescent material as a guest emitting material is a comparison of the excited singlet-state energies of the host and the fluorescent material. It is highly desirable that the excited singlet-state energy of the fluorescent material be lower than that of the host material. The excited singlet-state energy is defined as the difference in energy between the emitting singlet state and the ground state. For non-emissive hosts, the lowest excited state of the same electronic spin as the ground state is considered the emitting state.

Host and emitting materials known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

As described previously, metal complexes of 8-hydroxyquinoline and similar derivatives, also known as metal-chelated oxinoid compounds (Formula E), constitute one class of useful host compounds capable of supporting electroluminescence, and are particularly suitable for light emission of wavelengths longer than 500 nm, e.g., green, yellow, orange, and red. 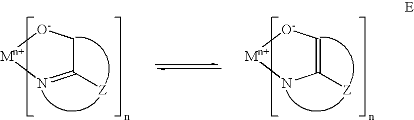
wherein
M represents a metal;
n is an integer of from 1 to 4; and
Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; a trivalent metal, such aluminum or gallium, or another metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III)]
CO-2: Magnesium bisoxine [alias, bis(8-quinolinolato)magnesium(II)]
CO-3: Bis[benzo{f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

As already mentioned, derivatives of 9,10-di-(2-naphthyl)anthracene (Formula F) constitute one class of useful host materials capable of supporting electroluminescence, and are particularly suitable for light emission of wavelengths longer than 400 nm, e.g., blue, green, yellow, orange or red. 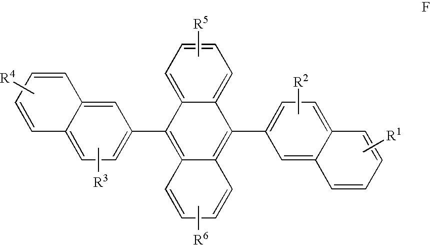
wherein: R¹, R², R³, R⁴, R⁵, and R⁶ represent one or more substituents on each ring where each substituent is individually selected from the following groups:
Group 1: hydrogen, or alkyl of from 1 to 24 carbon atoms;
Group 2: aryl or substituted aryl of from 5 to 20 carbon atoms;
Group 3: carbon atoms from 4 to 24 necessary to complete a fused aromatic ring of anthracenyl; pyrenyl, or perylenyl;
Group 4: heteroaryl or substituted heteroaryl of from 5 to 24 carbon atoms as necessary to complete a fused heteroaromatic ring of furyl, thienyl, pyridyl, quinolinyl or other heterocyclic systems;
Group 5: alkoxylamino, alkylamino, or arylamino of from 1 to 24 carbon atoms; and
Group 6: fluorine, chlorine, bromine or cyano.

Illustrative examples include 9,10-di-(2-naphthyl)anthracene and 2-t-butyl-9,10-di-(2-naphthyl)anthracene. Other anthracene derivatives can be useful as a host in the LEL, including derivatives of 9,10-bis[4-(2,2-diphenylethenyl)phenyl]anthracene.

Benzazole derivatives (Formula G) constitute another class of useful host materials capable of supporting electroluminescence, and are particularly suitable for light emission of wavelengths longer than 400 nm, e.g., blue, green, yellow, orange or red. 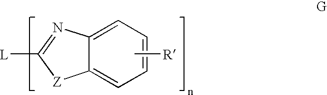
wherein:
n is an integer of 3 to 8;
Z is O, NR or S; and
R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring; and
L is a linkage unit consisting of alkyl, aryl, substituted alkyl, or substituted aryl, which connects the multiple benzazoles together. L may be either conjugated with the multiple benzazoles or not in conjugation with them. An example of a useful benzazole is 2,2′,2″-(1,3,5-phenylene)tris[1-phenyl-1H-benzimidazole].
Styrylarylene derivatives as described in U.S. Pat. No. 5,121,029 and JP 08333569 are also useful hosts for blue emission. For example, 9,10-bis[4-(2,2-diphenylethenyl)phenyl]anthracene and 4,4′-bis(2,2-diphenylethenyl)-1,1′-biphenyl (DPVBi) are useful hosts for blue emission.

Useful fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)amine boron compounds, bis(azinyl)methane compounds, and carbostyryl compounds. Illustrative examples of useful materials include, but are not limited to, the following:

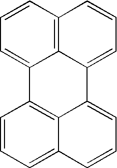

L1

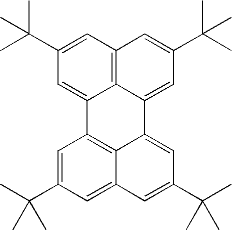

L2

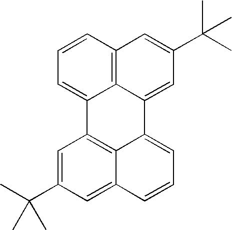

L3

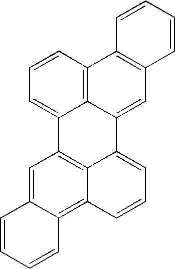

L4

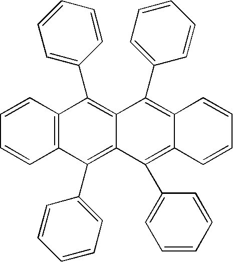

L5

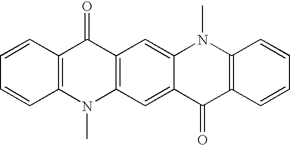

L6

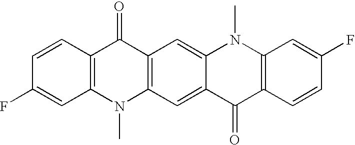

L7

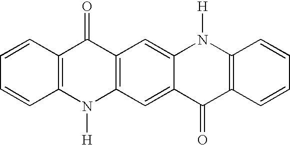

L8

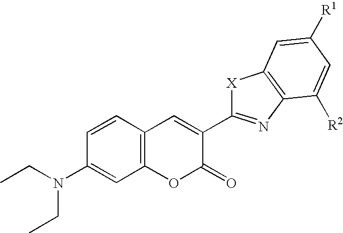

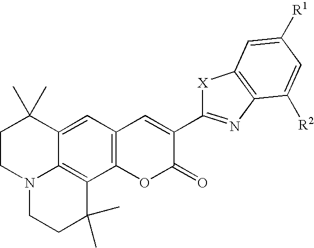

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

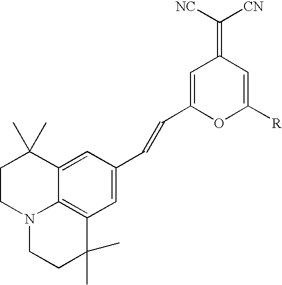

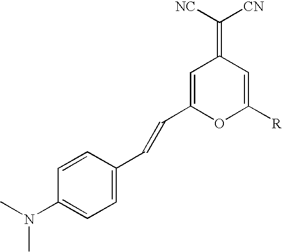

| | R |
|---|---|
| L37 | phenyl |
| L38 | methyl |
| L39 | t-butyl |
| L40 | mesityl |
| L41 | phenyl |
| L42 | methyl |
| L43 | t-butyl |
| L44 | mesityl |

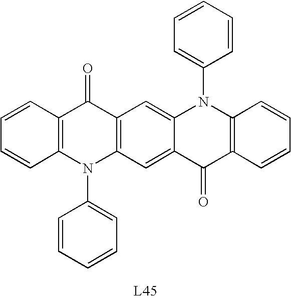

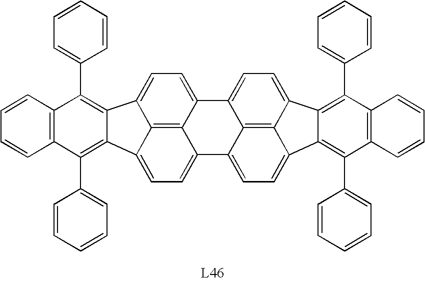

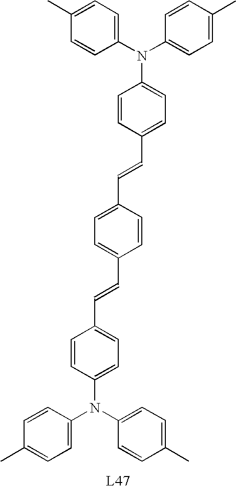

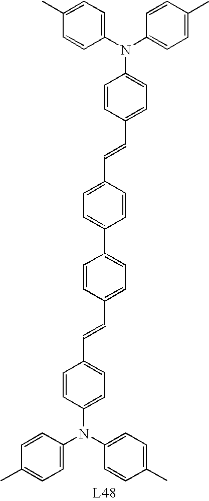

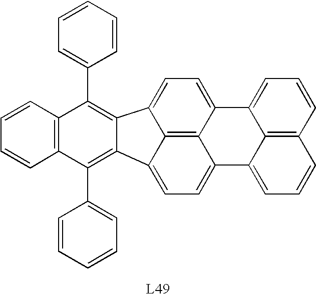

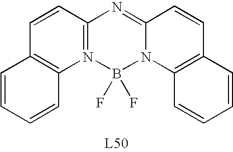

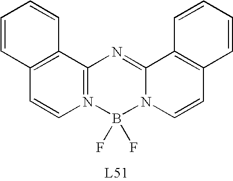

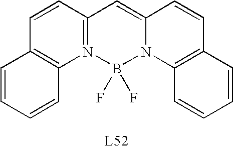

In addition to the light-emitting materials of this invention, light-emitting phosphorescent materials may be used in the EL device. For convenience, the phosphorescent complex guest material may be referred to herein as a phosphorescent material. The phosphorescent material typically includes one or more ligands, for example monoanionic ligands that can be coordinated to a metal through an sp² carbon and a heteroatom. Conveniently, the ligand can be phenylpyridine (ppy) or derivatives or analogs thereof. Examples of some useful phosphorescent organometallic materials include tris(2-phenylpyridinato-N,C^{2′})iridium(III), bis(2-phenylpyridinato-N,C²)iridium(III)(acetylacetonate), and bis(2-phenylpyridinato-N,C^{2′})platinum(II). Usefully, many phosphorescent organometallic materials emit in the green region of the spectrum, that is, with a maximum emission in the range of 510 to 570 nm.

Phosphorescent materials may be used singly or in combinations other phosphorescent materials, either in the same or different layers. Phosphorescent materials and suitable hosts are described in WO 00/57676, WO 00/70655, WO 01/41512 A1, WO 02/15645 A1, US 2003/0017361 A1, WO 01/93642 A1, WO 01/39234 A2, U.S. Pat. No. 6,458,475 B1, WO 02/071813 A1, U.S. Pat. No. 6,573,651 B2, US 2002/0197511 A1, WO 02/074015 A2, U.S. Pat. No. 6,451,455 B1, US 2003/0072964 A1, US 2003/0068528 A1, U.S. Pat. No. 6,413,656 B1, U.S. Pat. No. 6,515,298 B2, U.S. Pat. No. 6,451,415 B1, U.S. Pat. No. 6,097,147, US 2003/0124381 A1, US 2003/0059646 A1, US 2003/0054198 A1, EP 1 239 526 A2, EP 1 238 981 A2, EP 1 244 155 A2, US 2002/0100906 A1, US 2003/0068526 A1, US 2003/0068535 A1, JP 2003073387A, JP 2003 073388A, US 2003/0141809 A1, US 2003/0040627 A1, JP 2003059667A, JP 2003073665A, and US 2002/0121638 A1.

The emission wavelengths of cyclometallated Ir(III) complexes of the type IrL₃ and IrL₂L′, such as the green-emitting fac-tris(2-phenylpyridinato-N,C^{2′})iridium(III) and bis(2-phenylpyridinato-N,C^{2′})iridium(III)(acetylacetonate) may be shifted by substitution of electron donating or withdrawing groups at appropriate positions on the cyclometallating ligand L, or by choice of different heterocycles for the cyclometallating ligand L. The emission wavelengths may also be shifted by choice of the ancillary ligand L′. Examples of red emitters are the bis(2-(2′-benzothienyl)pyridinato-N,C^{3′})iridium(III)(acetylacetonate) and tris(2-phenylisoquinolinato-N, C)iridium(III). A blue-emitting example is bis(2-(4,6-difluorophenyl)-pyridinato-N, C^{2′})iridium(III)(picolinate).

Red electrophosphorescence has been reported, using bis(2-(2′-benzo[4,5-a]thienyl)pyridinato-N, C³) iridium (acetylacetonate) [Btp₂Ir(acac)] as the phosphorescent material (C. Adachi, S. Lamansky, M. A. Baldo, R. C. Kwong, M. E. Thompson, and S. R. Forrest, App. Phys. Lett., 78, 1622-1624 (2001)).

Other important phosphorescent materials include cyclometallated Pt(II) complexes such as cis-bis(2-phenylpyridinato-N, C^{2′})platinum(II), cis-bis(2-(2′-thienyl)pyridinato-N, C^{3′}) platinum(II), cis-bis(2-(2′-thienyl)quinolinato-N, C^{5′}) platinum(II), or (2-(4,6-difluorophenyl)pyridinato-N, C^{2′}) platinum (II) (acetylacetonate). Pt (II) porphyrin complexes such as 2,3,7,8,12,13,17,18-octaethyl-21H, 23H-porphine platinum(II) are also useful phosphorescent materials.

Still other examples of useful phosphorescent materials include coordination complexes of the trivalent lanthanides such as Tb³⁺ and Eu³⁺ (J. Kido et al., Appl. Phys. Lett., 65, 2124 (1994)).

Suitable host materials for phosphorescent materials should be selected so that transfer of a triplet exciton can occur efficiently from the host material to the phosphorescent material but cannot occur efficiently from the phosphorescent material to the host material. Therefore, it is highly desirable that the triplet energy of the phosphorescent material be lower than the triplet energy of the host. Generally speaking, a large triplet energy implies a large optical bandgap. However, the band gap of the host should not be chosen so large as to cause an unacceptable barrier to injection of charge carriers into the light-emitting layer and an unacceptable increase in the drive voltage of the OLED. Suitable host materials are described in WO 00/70655 A2; 01/39234 A2; 01/93642 A1; 02/074015 A2; 02/15645 A1, and US 20020117662. Suitable hosts include certain aryl amines, triazoles, indoles and carbazole compounds. Examples of desirable hosts are 4,4′-N,N′-dicarbazole-biphenyl, otherwise known as 4,4′-bis(carbazol-9-yl)biphenyl or CBP; 4,4′-N,N-dicarbazole-2,2′-dimethyl-biphenyl, otherwise known as 2,2′-dimethyl-4,4′-bis(carbazol-9-yl)biphenyl or CDBP; 1,3-bis(N,N′-dicarbazole)benzene, otherwise known as 1,3-bis(carbazol-9-yl)benzene, and poly(N-vinylcarbazole), including their derivatives.

Desirable host materials are capable of forming a continuous film.

Blocking Layers

In addition to suitable hosts, an OLED device employing a phosphorescent material often requires at least one hole-blocking layer (HBL) 110 placed between the electron-transporting layer 111 and the light-emitting layer 109 to help confine the excitons and recombination events to the light-emitting layer comprising the host and phosphorescent material. In this case, there should be an energy barrier for hole migration from the host into the hole-blocking layer, while electrons should pass readily from the hole-blocking layer into the light-emitting layer comprising a host and a phosphorescent material. The first requirement entails that the ionization potential of the hole-blocking layer be larger than that of the light-emitting layer 109, desirably by 0.2 eV or more. The second requirement entails that the electron affinity of the hole-blocking layer not greatly exceed that of the light-emitting layer 109, and desirably be either less than that of light-emitting layer or not exceed that of the light-emitting layer by more than about 0.2 eV.

When used with an electron-transporting layer whose characteristic luminescence is green, such as an Alq-containing electron-transporting layer as described below, the requirements concerning the energies of the highest occupied molecular orbital (HOMO) and lowest unoccupied molecular orbital (LUMO) of the material of the hole-blocking layer frequently result in a characteristic luminescence of the hole-blocking layer at shorter wavelengths than that of the electron-transporting layer, such as blue, violet, or ultraviolet luminescence. Thus, it is desirable that the characteristic luminescence of the material of a hole-blocking layer be blue, violet, or ultraviolet. It is further desirable, but not absolutely required, that the triplet energy of the hole-blocking material be greater than that of the phosphorescent material. Suitable hole-blocking materials are described in WO 00/70655A2 and WO 01/93642 A1. Two examples of useful hole-blocking materials are bathocuproine (BCP) and bis(2-methyl-8-quinolinolato)(4-phenylphenolato)aluminum(III) (BAlq). The characteristic luminescence of BCP is in the ultraviolet, and that of BAlq is blue. Metal complexes other than BAlq are also known to block holes and excitons as described in US 20030068528. In addition, US 20030175553 A1 describes the use of fac-tris(1-phenylpyrazolato-N,C^{2′})iridium(III) (Irppz) for this purpose.

When a hole-blocking layer is used, its thickness can be between 2 and 100 nm and suitably between 5 and 10 nm.

An OLED device employing a phosphorescent emitter may include at least one exciton blocking layer, 108, placed adjacent the light emitting layer 109 on the anode side, to help confine triplet excitons to the light emitting layer comprising a host or co-hosts and a phosphorescent emitter. In order that the exciton blocking layer be capable of confining triplet excitons, the material or materials of this layer should have triplet energies that exceed that of the phosphorescent emitter. Otherwise, if the triplet energy level of any material in the layer adjacent the light emitting layer is lower than that of the phosphorescent emitter, often that material will quench excited states in the light emitting layer, decreasing device luminous efficiency. In some cases it is also desirable that the exciton blocking layer also help to confine electron-hole recombination events to the light emitting layer by blocking the escape of electrons from the light emitting layer into the exciton blocking layer. In order that the exciton blocking layer have this electron blocking property, the material or materials of this layer should have solid-state electron affinities that exceed the electron affinities of the materials in the light emitting layer by at least 0.1 eV and preferably by at least 0.2 eV.

Electron-Transporting Layer (ETL)

Desirable thin film-forming materials for use in forming the electron-transporting layer 111 of the organic EL devices of this invention are metal-chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary of contemplated oxinoid compounds are those satisfying structural formula (E), previously described.

Other electron-transporting materials suitable for use in the electron-transporting layer 111 include various butadiene derivatives as disclosed in U.S. Pat. No. 4,356,429 and various heterocyclic optical brighteners as described in U.S. Pat. No. 4,539,507. Benzazoles satisfying structural formula (G) are also useful electron transporting materials. Triazines are also known to be useful as electron transporting materials.

If both a hole-blocking layer and an electron-transporting layer 111 are used, electrons should pass readily from the electron-transporting layer 111 into the hole-blocking layer. Therefore, the electron affinity of the electron-transporting layer 111 should not greatly exceed that of the hole-blocking layer. Desirably, the electron affinity of the electron-transporting layer should be less than that of the hole-blocking layer or not exceed it by more than about 0.2 eV.

If an electron-transporting layer is used, its thickness may be between 2 and 100 nm and suitably between 5 and 20 nm.

Other Useful Organic Layers and Device Architecture

In some instances, layers 109 through 111 can optionally be collapsed into a single layer that serves the function of supporting both light emission and electron transportation. The hole-blocking layer, when present, and layer 111 may also be collapsed into a single layer that functions to block holes or excitons, and supports electron transport. It also known in the art that emitting materials may be included in the hole-transporting layer 107. In that case, the hole-transporting material may serve as a host. Multiple materials may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, US 20020025419, EP 1 182 244, U.S. Pat. No. 5,683,823, U.S. Pat. No. 5,503,910, U.S. Pat. No. 5,405,709, and U.S. Pat. No. 5,283,182 and can be equipped with a suitable filter arrangement to produce a color emission.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited by any means suitable for the form of the organic materials. In the case of small molecules, they are conveniently deposited through sublimation or evaporation, but can be deposited by other means such as coating from a solvent together with an optional binder to improve film formation. If the material is a polymer, solvent deposition is usually preferred. The material to be deposited by sublimation or evaporation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,688,551, U.S. Pat. No. 5,851,709 and U.S. Pat. No. 6,066,357) or an inkjet method (U.S. Pat. No. 6,066,357).

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOₓ, Teflon, and alternating inorganic/polymeric layers are known in the art for encapsulation. Any of these methods of sealing or encapsulation and desiccation can be used with the EL devices constructed according to the present invention.

Optical Optimization

OLED devices of this invention can employ various well-known optical effects in order to enhance their emissive properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing colored, neutral density, or color-conversion filters over the display. Filters, polarizers, and anti-glare or anti-reflection coatings may be specifically provided over the EL device or as part of the EL device.

Embodiments of the invention can provide advantageous features such as luminous yield, lower drive voltage, and power efficiency, improved operational stability, or reduced sublimation temperatures. Embodiments of the compounds useful in the invention can provide a wide range of hues including those useful in the emission of white light (directly or through filters to provide multicolor displays). Embodiments of the invention can also provide an area lighting device.

The invention and its advantages can be better appreciated by the following examples.

### SYNTHETIC EXAMPLE

### Preparation of Inv-1

a) Preparation of 9-bromo-10-phenylanthracene. A mixture of 9.7 g (38 mmol) of 9-phenylanthracene, 12.5 g (76 mmol) of N-bromosuccinimide (NBS), and 80 mL of N,N-dimethylformamide (DMF) was stirred under an argon atmosphere at room temperature for 40 h. The precipitated product was collected, washed with methanol, and dried to afford 5.7 g (45% yield) of the product as a light yellow powder. ¹H NMR (CDCl₃) δ 7.4 (m, 4H), 7.6 (m, 7H), 8.61 (d, 2H). Field-desorption mass spectroscopy (FD-MS) m/e 332, 334 (M⁺, Br₁).
b) Preparation of 9-phenyl-10-phenylethynylanthracene. A mixture of 3.90 g (11.7 mmol) of 9-bromo-10-phenylanthracene, 1.55 g (14 mmol) of phenyl acetylene, 2.43 g (16 mmol) of 1,8-diazabicyclo[5.4.0]undec-7-ene (DBU), and 30 mL of toluene was deoxygenated by sparging with argon for 10 min. Bis(triphenylphosphine)palladium (II) chloride (0.16 g, 0.2 mmol) and 0.11 g (0.6 mmol) of copper (I) iodide were added, and the mixture was heated at reflux under argon for 15 h. An additional 1.0 g (9 mmol) of phenyl acetylene was added, and the reaction was continued for 24 h. The mixture was cooled to room temperature, and passed through a short column of silica gel, eluting with additional toluene. The eluate was concentrated, and the residue was recrystallized from ethyl acetate to afford 2.25 g (54% yield) of the product as a yellow powder. ¹H NMR (CDCl₃) δ 7.4 (m, 7H), 7.55 9M, 5H), 7.65 (d, 2H), 7.80 (d, 2H), 8.75 (d, 2H). FD-MS m/e 354 (M⁺).

### SYNTHETIC EXAMPLE

### Preparation of Inv-2

Preparation of 9-phenyl-10-((4-tert-butylphenyl)ethynyl)anthracene. A mixture of 3.00 g (9.0 mmol) of 9-bromo-10-phenylanthracene, 2.14 g (14 mmol) of 4-tert-butylphenyl acetylene, 2.0 g (15 mmol) of DBU, and 70 mL of toluene was deoxygenated by sparging with argon for 5 min. Bis(triphenylphosphine)palladium (II) chloride (0.16 g, 0.2 mmol) and 0.11 g (0.6 mmol) of copper (I) iodide were added, and the mixture was heated at reflux under argon for 15 h. An additional 1.0 g (6.3 mmol) of 4-tert-butylphenyl acetylene and 1.0 g of DBU were added, and the reaction was continued for 2 h. The mixture was cooled to room temperature, diluted with dichloromethane, and passed through a short column of silica gel, eluting with additional toluene. The eluate was concentrated, and the crude product was purified by column chromatography followed by recrystallization from heptane to afford 1.2 g (33% yield) of the product as a yellow powder. ¹H NMR (CDCl₃) δ 1.35 (s, 9H), 7.4 (m, 6H), 7.58 (m, 5H), 7.65 (d, 2H), 7.75 (d, 2H), 8.73 (d, 2H). FD-MS m/e 410 (M⁺).

### SYNTHETIC EXAMPLE

### Preparation of Inv-47

a) Preparation of 9-(4-biphenyl)anthracene. A mixture of 10.0 g (39 mmol) of 9-bromoanthracene, 8.47 g (43 mmol) of biphenyl 4-boronic acid, 4.12 g (39 mmol) of sodium carbonate, 70 mL of 1,2-dimethoxyethane (DME), 30 mL of water, and 20 mL of ethanol was deaerated by sparging with argon for 10 min. Bis(triphenylphosphine)palladium (II) chloride (0.27 g, 0.4 mmol) was added, and the mixture was sparged with argon for 5 min. The stirred mixture was heated at reflux under argon for 24 h, then cooled to room temperature. Dichloromethane (200 mL) and water (100 mL) were added with stirring. The organic layer was separated, washed successively with 100 mL of water and then with 100 mL of brine, dried (MgSO₄), and passed through a short column of silica gel (to remove residual catalyst), eluting with additional dichloromethane. The eluate was concentrated to deposit a pale green solid, which was then recrystallized from 50% toluene/50% heptane to deposit 9.81 g (76% yield) of the product. ¹H NMR (CDCl₃) δ 7.3-7.6 (m, 9H), 7.8 (m, 6H), 8.05 (d, 2H), 8.51 (s, 1H). Integrated gas chromatography-electron impact mass spectrometry (GC-MS) m/e 330 (M⁺).
b) Preparation of 9-bromo-10-(4-biphenyl)anthracene. A mixture of 9.80 g (30 mmol) of 9-(4-biphenyl)anthracene, 10.56 g (59 mmol) of NBS, and 100 mL of carbon tetrachloride was stirred at reflux for 42 h. The mixture was cooled to room temperature, the precipitated by-product of succinimide was filtered, and the eluate was concentrated to deposit a yellow solid, which was then washed with methanol and filtered. The solid was recrystallized from 50% toluene/50% heptane to deposit 9.30 g (76% yield) of the product. ¹H NMR (CDCl₃) δ 7.3-7.6 (m, 9H), 7.8 (m, 6H), 8.65 (d, 2H). GC-MS m/e 408, 410 (M⁺, Br₁).
c) Preparation of 9-(4-biphenyl)-10-((4-biphenyl)ethynyl)anthracene. A mixture of 3.50 g (8.6 mmol) of 9-bromo-10-(4-biphenyl)anthracene, 1.83 g (10 mmol) of 4-ethynylbiphenyl, 1.95 g (13 mmol) of DBU, and 40 mL of toluene was deoxygenated by sparging with argon for 10 min. Bis(triphenylphosphine)palladium (II) chloride (0.06 g, 0.09 mmol) and 0.081 g (0.4 mmol) of copper (I) iodide were added, and the mixture was heated at reflux under argon for 4 h. The mixture was cooled to room temperature, and the precipitated crude product was collected. The crude product was extracted with dichloromethane for 18 d in a Soxhlet apparatus, and the pure product was obtained as 1.05 g (24% yield) as a yellow powder. ¹H NMR (CDCl₂—CDCl₂, 40° C.) δ 7.4 (m, 6H), 7.58 (m, 5H), 7.65 (d, 2H), 7.75 (d, 2H), 8.73 (d, 2H). FD-MS m/e 506 (M⁺).
d) Synthesis of 9-(4-biphenyl)-10-phenylethynylanthracene. A mixture of 4.00 g (9.8 mmol) of 9-bromo-10-(4-biphenyl)anthracene, 1.18 g (11 mmol) of 4-ethynylbiphenyl, 2.23 g (15 mmol) of DBU, and 40 mL of toluene was deoxygenated by sparging with argon for 10 min. Bis(triphenylphosphine)palladium (II) chloride (0.06 g, 0.09 mmol) and 0.081 g (0.4 mmol) of copper (I) iodide were added, and the mixture was heated at reflux under argon for 6 h. An additional 1.0 g (9 mmol) of phenylacetylene was added, and the reaction was continued for 18 h. The mixture was cooled to room temperature, passed through a short column of silica gel, eluting with dichloromethane. The eluate was concentrated to deposit the crude product, which was purified by column chromatography (silica gel, hexanes/dichloromethane eluents) followed by recrystallization from toluene. The pure product was obtained as 1.06 g (24% yield) as a yellow powder. ¹H NMR (CDCl₃) δ 7.4-7.9 (m, 20H), 8.74 (d, 2H). FD-MS m/e 430 (M⁺).

### SYNTHETIC EXAMPLE

### Preparation of Inv-52

a) Preparation of 9-(3-biphenyl)anthracene. A mixture of 6.0 g (23 mmol) of 9-bromoanthracene, 5.08 g (26 mmol) of biphenyl 3-boronic acid, 2.47 g (23 mmol) of sodium carbonate, 70 mL of DME, 30 mL of water, and 20 mL of ethanol was deaerated by sparging with argon for 10 min. Bis(triphenylphosphine)palladium (II) chloride (0.16 g, 0.23 mmol) was added, and the mixture was sparged with argon for 5 min. The stirred mixture was heated at reflux under argon for 30 h, then cooled to room temperature. Dichloromethane (150 mL) and water (100 mL) were added with stirring. The organic layer was separated, washed successively with 100 mL of water and then with 100 mL of brine, dried (MgSO₄), and passed through a short column of silica gel (to remove residual catalyst), eluting with additional dichloromethane. The eluate was concentrated to deposit a yellow oil, which was triturated with ligroin and held at −20° C. to deposit the crude product as white crystals. The product was then recrystallized from heptane to deposit 5.85 g (76% yield) of the product. ¹H NMR (CDCl₃) δ 7.3-7.5 (m, 9H), 7.7 (m, 6H), 8.05 (d, 2H), 8.51 (s, 1H). FD-MS m/e 330 (M⁺).

b) Preparation of 9-bromo-10-(3-biphenyl)anthracene. A mixture of 5.85 g (17.7 mmol) of 9-(3-biphenyl)anthracene, 6.30 g (35 mmol) of NBS, and 50 mL of carbon tetrachloride was stirred at reflux under nitrogen 18 h, then 2.0 g (11 mmol) of additional NBS was added, and the reaction continued for 20 h. The mixture was cooled to room temperature, the precipitated by-product of succinimide was filtered, and the eluate was concentrated to deposit a gold glass, which was triturated with methanol and stored at −20° C. to produce a crystalline crude product. The crude product was recrystallized from isopropanol to deposit 3.12 g (43% yield) of the product.

c) Preparation of 9-(4-biphenyl)-10-((3-biphenyl)ethynyl)anthracene. A mixture of 4.05 g (9.9 mmol) of 9-bromo-10-(3-biphenyl)anthracene, 1.94 g (11 mmol) of 4-ethynylbiphenyl, 1.81 g (11 mmol) of DBU, and 40 mL of toluene was deoxygenated by sparging with nitrogen for 10 min. Bis(triphenylphosphine)palladium (II) chloride (0.034 g, 0.048 mmol) and 0.047 g (0.24 mmol) of copper (I) iodide were added, and the mixture was heated at reflux under argon for 16 h. The mixture was cooled to room temperature, and 100 mL of dichloromethane was added. The resulting solution was passed through a short column of silica gel (to remove residual catalyst), eluting with additional dichloromethane. The eluate was washed successively with water and then with brine, dried (MgSO₄), and concentrated to deposit the crude product, which was purified by column chromatography (silica gel, hexanes/dichloromethane eluents) followed by recrystallization from 20% isopropanol/80% toluene. The pure product was obtained as 1.73 g (35% yield) as a yellow powder. ¹H NMR (CDCl₃) δ 7.3-7.5 (m, 9H), 7.6-7.8 (m, 13H), 7.86 (d, 2H), 8.76 (d, 2H). FD-MS m/e 506 (M⁺).

### SYNTHETIC EXAMPLE

### Preparation of Inv-48

a) Preparation of 9-(2-biphenyl)anthracene. A mixture of 10.5 g (41 mmol) of 9-bromoanthracene, 8.90 g (45 mmol) of biphenyl 2-boronic acid, 28.34 g (90 mmol) of barium hydroxide octahydrate, 100 mL of toluene, and 50 mL of water was deaerated by sparging with argon for 5 min. Bis(triphenylphosphine)palladium (II) chloride (0.29 g, 0.41 mmol) was added, and the mixture was sparged with argon for 5 min. The stirred mixture was heated at reflux under argon for 18 h, then cooled to room temperature. Dichloromethane (100 mL) and water (100 mL) were added with stirring. The heterogeneous mixture was filtered, and the precipitate was washed with dichloromethane. The organic layer from the combined filtrates was separated, dried (MgSO₄), and concentrated to deposit a light yellow solid. The solid was recrystallized from 80% heptane/20% toluene to deposit 10.0 g (74% yield) of the product as a yellow powder. GC-MS m/e 330 (M⁺).

b) Preparation of 9-bromo-10-(2-biphenyl)anthracene. A mixture of 2.37 g (7.2 mmol) of 9-(2-biphenyl)anthracene, 2.55 g (14 mmol) of NBS, and 25 mL of carbon tetrachloride was stirred at reflux under nitrogen 18 h, then 2.0 g (11 mmol) of additional NBS was added, and the reaction continued for 20 h. Four drops of bromine were added, and the reaction was continued for 30 min. The mixture was cooled to room temperature, the precipitated by-product of succinimide was filtered, and the eluate was concentrated to deposit a yellow glass, which triturated with methanol and stored at −10° C. to produce a crystalline crude product. The crude product was recrystallized from heptane to deposit 2.01 g (68% yield) of the product. ¹H NMR (CDCl₃) δ 6.8-7.0 (m, 5H), 7.33 (m, 3H), 7.5 (m, 3H), 7.6 (m, 4H), 8.50 (d, 2H).

c) Preparation of 9-(2-biphenyl)-10-((4-biphenyl)ethynyl)anthracene. A mixture of 2.00 g (4.9 mmol) of 9-bromo-10-(2-biphenyl)anthracene, 0.96 g (5.4 mmol) of 4-ethynylbiphenyl, 0.89 g (5.9 mmol) of DBU, and 40 mL of toluene was deoxygenated by sparging with nitrogen for 10 min. Bis(triphenylphosphine)palladium (II) chloride (0.034 g, 0.048 mmol) and 0.047 g (0.24 mmol) of copper (I) iodide were added, and the mixture was heated at reflux under argon for 16 h. Additional 4-ethynylbiphenyl (0.2 g, 1.1 mmol), bis(triphenylphosphine)palladium (II) chloride (0.010 g, 0.014 mmol), and DBU (0.5 g, 3.2 mmol) were added, and the reaction was continued for 20 h. The mixture was cooled to room temperature, and 50 mL of dichloromethane was added. The resulting solution was passed through a short column of silica gel (to remove residual catalyst), eluting with additional dichloromethane. The eluate was concentrated to deposit the crude product, which was purified by column chromatography (silica gel, hexanes/dichloromethane eluents) followed by recrystallization from toluene. The pure product was obtained as 1.06 g (24% yield) as a yellow powder. ¹H NMR (CDCl₃) δ 6.86 (m, 3H), 6.95 (m, 2H), 7.4 (m, 4H), 7.5 (m, 5H), 7.65 (m, 8H), 7.83 (d, 2H), 8.66 (d, 2H). GC-MS m/e 506 (M⁺).

### SYNTHETIC EXAMPLE

### Preparation of Inv-51

Preparation of 9-(2-biphenyl)-10-(phenylethynyl)anthracene. A mixture of 4.00 g (9.8 mmol) of 9-bromo-10-(2-biphenyl)anthracene, 1.20 g (11.7 mmol) of phenylacetylene, 1.79 g (11.7 mmol) of DBU, and 50 mL of toluene was deoxygenated by sparging with nitrogen for 10 min. Bis(triphenylphosphine)palladium (II) chloride (0.069 g, 0.010 mmol) and 0.093 g (0.49 mmol) of copper (I) iodide were added, and the mixture was heated at reflux under argon for 18 h. The mixture was cooled to room temperature, and 50 mL of dichloromethane was added. The resulting solution was passed through a short column of silica gel (to remove residual catalyst), eluting with additional dichloromethane. The eluate was concentrated to deposit the crude product, which was purified by column chromatography (silica gel, hexanes/dichloromethane eluents) followed by recrystallization from 95% ethyl acetate/5% toluene. The pure product was obtained as 3.36 g (80% yield) of orange cubic crystals. ¹H NMR (CDCl₃) δ 6.88 (m, 3H), 6.98 (m, 2H), 7.3-7.6 (m, 9H), 7.65 (m, 4H), 7.77 (m, 2H), 8.67 (d, 2H). FD-MS m/e 430 (M⁺).

### SYNTHETIC EXAMPLE

### Preparation of Inv-37

Preparation of 9-(4-tert-butylphenyl)-10-(4-tert-butylphenyl)anthracene. A mixture of 2.84 g (7.3 mmol) of 9-bromo-10-(4-tert-butylphenyl)anthracene, 1.39 g (8.8 mmol) of 4-tert-butylphenylacetylene, 1.33 g (8.8 mmol) of DBU, and 40 mL of toluene was deoxygenated by sparging with nitrogen for 5 min. Bis(triphenylphosphine)palladium (II) chloride (0.102 g, 0.15 mmol) and 0.069 g (0.36 mmol) of copper (I) iodide were added, and the mixture was heated at reflux under argon for 16 h. The mixture was cooled to room temperature, and 75 mL of dichloromethane and 75 mL of water were added. The organic layer was separated, and the aqueous layer was extracted with 50 mL of dichloromethane. The combined organic extracts were washed with brine, dried (MgSO₄), and concentrated to deposit the crude product, which was purified by column chromatography (silica gel, hexanes/dichloromethane eluents) followed by recrystallization from 50% toluene/50% heptane. The pure product was obtained as 1.50 g (44% yield) of a yellow powder. ¹H NMR (CDCl₃) δ 1.38 (s, 9H), 1.47 (s, 9H), 7.35 (m, 4H), 7.48 (d, 2H), 7.57 (t, 4H), 7.72 (m, 4H), 8.73 (d, 2H). FD-MS m/e 466 (M⁺).

### SYNTHETIC EXAMPLE

### Preparation of Inv-59

a) Preparation of 9-(2-naphthyl)anthracene. 9-Bromoanthracene (12 g, 46 mmo) and 2-naphthalenboronic acid (8.0 g, 46 mmol) were combined in 100 ml of toluene and the resulting mixture was degassed by sonication for about 15 min. Bis(triphenylphosphine) palladium (II) chloride (0.110 g, 0.095 mmol) was added and the resulting mixture was thoroughly stirred under nitrogen while 100 ml of 2M Na₂CO₃ was added, and the mixture heated to reflux overnight with a heating mantle. The reaction mixture was cooled to room temperature at which time solid began to precipitate. The solid was isolated by filtration, washed with water, and air dried to yield 11.4 g (80%) of product. Additional extraction of the organic layer with methylene chloride followed by drying over MgSO4 and concentration, yielded another 2 g of product, for a total of 94% yield.
b) Preparation of 9-(3-bromobenzene)-10-(2-Naphthyl)ethynyl anthracene. Preparation of 9-bromo, 10-(2-naphthyl)anthracene. 9-(2-naphthyl)anthracene (14 g, 48 mmol) and N-bromosuccinimide (8.9 g, 50 mmol) were combined with 140 ml CH₂Cl₂ in a 500 ml round bottom flask. The mixture was stirred at room temperature under nitrogen in the presence of light from a 100 W incandescent lamp and the mixture quickly became homogeneous. Reaction was complete after 3 h, as indicated by TLC (ligroin:CH₂Cl₂/9:1). Approximately half of the solvent volume was stripped off until a solid started to precipitate. Enough acetonitrile was added with heating to dissolve the solid. Additional CH₂Cl₂ was then stripped off to the point where solid began to precipitate. The solution was cooled, and the product crystallized. The resulting solid was isolated by filtration, washed with a small amount of acetonitrile, and dried to yield 17 g (92%).
c) Preparation of 9-(trimethylsilylethynyl)-10-(2-naphthyl)anthracene. 9-bromo-10-(2-naphthyl)anthracene (24.7 g, 74 mmol) was combined with copper (I) iodide (0.28 g, 1.48 mmol), and bis(triphenylphosphine) palladium (II) chloride (0.28 g, 0.4 mmol) in 220 mL of degassed toluene. 1,8-Diazabicyclo[5.4.0]undec-7-ene (DBU) (16.6 mL, 111 mmol) was added in one portion. Timethylsilyl acetylene was added (14 mL, 99 mmol) in one portion, and the resulting mixture was brought to reflux and held for 1 h. The mixture was cooled. Solid by-products were removed by filtration, and these solids were washed with isopropyl ether to extract all of the product. The combined filtrates were concentrated, and the residue was passed through a short column of silica gel to remove trace impurities (eluating with ligroin:CH₂Cl₂/95:5). The product was recovered in 96% yield (25 g)

### SYNTHETIC EXAMPLE

### Preparation of Inv-72

a) Preparation of 9-ethynyl-10-(2-naphthyl)anthracene. To a suspension of 9-(trimethylsilylethynyl)-10-(2-naphthyl)anthracene (25 g, 71.6 mmol) in 250 mL of methanol under nitrogen, 8 g (143 mmol) of solid KOH was added. The resulting mixture was heated at 60° C. for 2 h. The precipitated product was isolated by filtration. The filtrate was concentrated, cooled, and additional precipitated product was isolated by filtration. A total of 14.8 g of product was obtained.
b) A 100 mL round bottom flask was charged with dry toluene, 3-bromobenzonitrile (0.83 g, 4.5 mmol), copper (I) iodide (17 mg, 0.09 mmol) and (bistriphenylphosphine)palladium (II) chloride (16 mg, 0.02 mmo. The resulting suspension was sonicated under nitrogen for 30 min, followed by the addition of DBU (0.95 mL, 4.5 mmol) and 9-ethynyl-10-(2-naphthyl)anthracene (1.5 g, 4.5 mmol, 1 eq). The reaction mixture was heated at 70° C. for 40 min and then cooled. The mixture was filtered to remove inorganic solids and the filter cake washed with methylene chloride to extract residual product. The combined filtrates were partially concentrated and passed through a short column of silica gel to remove trace impurities. The eluate was concentrated to yield 1.57 g of product (80%).

, silicon compounds with the silicon attached on the 9 or 10 position of the anthracene, such as Inv-55, can be easily prepared by conventional methods. For example, 9-bromoanthracene can be treated with butyllithium, followed by the addition of the chlorosilane of choice in the presence of KCN. Once the silane-substituted anthracene is obtained, bromination of the 10-position of the anthracene can be easily accomplished by methods similar to those in the above examples, followed by Sonogashira coupling with the alkyne of choice, to obtain the final product.

### DEVICE EXAMPLES 1-21

### EL Device Fabrication

An EL device satisfying the requirements of the invention was constructed in the following manner:
1. A glass substrate coated with an 85 nm layer of indium-tin oxide (ITO) as the anode was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃.
3. A hole-transporting layer (HTL) of N,N′-di-1-naphthyl-N,N′-diphenyl-4,4′-diaminobiphenyl (NPB) having a thickness of 75 nm was then deposited by evaporation in vacuo from a tantalum boat.
4. A 20 nm light-emitting layer (LEL) of 2-t-butyl-9,10-di-(2-naphthyl)anthracene (TBADN) as host, and compounds of this invention or tetra-t-butylperylene (TBP) as standard at various percentages as indicated in Table 1 were then deposited in vacuo from tantalum boats onto the hole-transporting layer.
5. A 40 nm electron-transporting layer (ETL) of tris(8-quinolinolato)aluminum (III) (AlQ₃) was then deposited in vacuo from a tantalum boat onto the light-emitting layer.
6. On top of the AlQ₃ layer was deposited a 220 nm cathode formed of a 10:1 volume ratio of Mg and Ag.

The above sequence completed the deposition of the EL device. The device was then hermetically packaged in a dry glove box for protection against ambient environment.

The cells thus formed in Examples 1-5 were tested for efficiency in the form of luminance yield (cd/A) measured at 20 mA/cm². CIE (Commission Internationale de L'Eclairage) color x and y coordinates were determined, and the results are reported in Table 1 in the form of output efficiency (W/A), luminance yield (cd/A), maximum wavelength (λmax) of emission and CIE coordinates. The problem to be solved is to prepare new emissive materials with a deep blue, or blue-green color. One of the advantages of the compounds of this invention is that the emission color can be fine tuned by manipulating the nature of the substituents on the ethynyl anthracenes. In Table 1 we report a series of inventive compounds that have a shorter blue color than the internal check TBP, used as a standard. In all of our measurements we used TBP as an internal control to have a relative comparison that includes experimental deviations.

TABLE 1
Electroluminescence data for Inv-2, Inv-8, Inv-11a, Inv-11b, Inv-20,
Inv-37, reported relative to TBP (internal check).

| | | TBP | Effi- | | | | |
|---|---|---|---|---|---|---|---|
| Ex- | Level | Level | ciency | | | λmax | |
| ample | (%) of Inv | (%) | (W/A) | CIEx | CIEy | (nm) | Type |
| 1 | 0.5 Inv-1 | 0.0 | 0.039 | 0.159 | 0.161 | 452 | Com- |
| | | | | | | | parative |
| 2 | 1.0 Inv-1 | 0.0 | 0.041 | 0.158 | 0.169 | 452 | Com- |
| | | | | | | | parative |
| 3 | 0.0 | 1.0 | 0.045 | 0.147 | 0.200 | 464 | Standard |
| 4 | 0.5 Inv-2 | 0.0 | 0.044 | 0.153 | 0.139 | 452 | Inventive |
| 5 | 1.0 Inv-2 | 0.0 | 0.044 | 0.152 | 0.148 | 452 | Inventive |
| 6 | 0.0 | 1.0 | 0.046 | 0.144 | 0.180 | 460 | Standard |
| 7 | 0.5 Inv-8 | 0.0 | 0.044 | 0.153 | 0.138 | 452 | Inventive |
| 8 | 1.0 Inv-8 | 0.0 | 0.043 | 0.152 | 0.142 | 452 | Inventive |
| 9 | 0.0 | 1.0 | 0.045 | 0.144 | 0.179 | 460 | Standard |
| 10 | 0.5 Inv-11b | 0.0 | 0.040 | 0.157 | 0.159 | 452 | Inventive |
| 11 | 1.0 Inv-11b | 0.0 | 0.038 | 0.157 | 0.163 | 452 | Inventive |
| 12 | 0.0 | 1.0 | 0.045 | 0.145 | 0.189 | 460 | Standard |
| 13 | 0.5 Inv-11a | 0.0 | 0.043 | 0.153 | 0.147 | 452 | Inventive |
| 14 | 1.0 Inv-11a | 0.0 | 0.044 | 0.151 | 0.155 | 452 | Inventive |
| 15 | 0.0 | 1.0 | 0.046 | 0.143 | 0.178 | 460 | Standard |
| 16 | 0.5 Inv-20 | 0.0 | 0.047 | 0.155 | 0.151 | 452 | Inventive |
| 17 | 1.0 Inv-20 | 0.0 | 0.045 | 0.154 | 0.153 | 452 | Inventive |
| 18 | 0.0 | 1.0 | 0.052 | 0.144 | 0.190 | 464 | Standard |
| 19 | 0.5 Inv-37 | 0.0 | 0.052 | 0.152 | 0.154 | 456 | Inventive |
| 20 | 1.0 Inv-37 | 0.0 | 0.052 | 0.151 | 0.162 | 456 | Inventive |
| 21 | 0.0 | 1.0 | 0.046 | 0.145 | 0.180 | 460 | Standard |

As can be seen from Table 1, all of the tested devices containing the inventive materials show a shorter blue color than the TBP internal control (standard), while the efficiency is comparable to that of TBP.

### DEVICE EXAMPLES 22-55

Devices 22-55 were fabricated in the same manner as described above except that the emitting layer contains Inv-3, Inv-4, Inv-5, Inv-6, Inv-7, Inv-9a, Inv-46 and Inv-47, respectively. As stated before, TPB was used as an internal check, and the performance of each inventive example is relative to that of TBP in the same run. The luminance loss was measured by subjecting the cells to a constant current density of 20 mA/cm² at 25° C. Stability for use in a display device is desirably less than about 40% loss after about 300 hours under these accelerated aging conditions. The luminance of the cell after operating for a certain period of time relative to the initial luminance is listed in Tables 2-9 as a percentage under the column titled ‘Stability’. To provide comparable numbers, the luminance of each cell was then plotted versus time. The resulting plot mathematically fitted to a stretched exponential equation. This equation was then used to determine the amount of time the cell could operate before its luminance would decrease 50% relative to the initial luminance. This value is reported in Tables 2-9 as 'T50 extrapolated.

TABLE 2
Electroluminescence and stability data for Inv-3.

| | Inv-3 | TBP | | | | Emission | | | |
|---|---|---|---|---|---|---|---|---|---|
| | Level | Level | Efficiency | | | λmax | Stability | T50 | |
| Example | (%) | (%) | (W/A) | CIEx | CIEy | (nm) | (%) | Extrapolated | Type |
| 22 | 0.5 | 0.0 | 0.051 | 0.149 | 0.192 | 456 | 87 | 2248 h | Inventive |
| 23 | 1.0 | 0.0 | 0.05 | 0.148 | 0.201 | 460 | 90 | 2201 h | Inventive |
| 24 | 1.5 | 0.0 | 0.049 | 0.149 | 0.211 | 460 | 90 | 2091 | Inventive |
| 25 | 2.0 | 0.0 | 0.047 | 0.148 | 0.212 | 460 | 90 | 2508 | Inventive |
| 26 | 0.0 | 1.0 | 0.050 | 0.143 | 0.208 | 464 | 91 | 1916 | Standard |

The above data show that Inv-3 has comparable blue color and efficiency to the standard dopant. In addition, the stability is improved.

TABLE 3
Electroluminescence and stability data for Inv-4.

| | Inv-4 | TBP | | | | Emission | | | |
|---|---|---|---|---|---|---|---|---|---|
| | Level | Level | Efficiency | | | λmax | Stability | T50 | |
| Example | (%) | (%) | (W/A) | CIEx | CIEy | (nm) | (%) | Extrapolated | Type |
| 27 | 0.75 | 0.0 | 0.050 | 0.152 | 0.185 | 460 | 85 | 2284 h | Inventive |
| 28 | 1.0 | 0.0 | 0.050 | 0.150 | 0.190 | 460 | 87 | 2604 h | Inventive |
| 29 | 0.0 | 1.0 | 0.047 | 0.146 | 0.189 | 460 | 85 | 1500 h | Standard |

The above data show that Inv-4 has comparable blue color and efficiency to the standard dopant. In addition, the stability is improved.

TABLE 4
Electroluminescence and stability data for Inv-5.

| | Inv-5 | TBP | | | | Emission | | | |
|---|---|---|---|---|---|---|---|---|---|
| | Level | Level | Efficiency | | | λmax | Stability | T50 | |
| Example | (%) | (%) | (W/A) | CIEx | CIEy | (nm) | (%) | Extrapolated | Type |
| 30 | 0.5 | 0.0 | 0.048 | 0.150 | 0.200 | 460 | 92 | 4124 h | Inventive |
| 31 | 1.0 | 0.0 | 0.048 | 0.150 | 0.207 | 460 | 93 | 3962 h | Inventive |
| 32 | 2.0 | 0.0 | 0.044 | 0.151 | 0.224 | 460 | 89 | 3583 | Inventive |
| 33 | 0.0 | 1.0 | 0.049 | 0.143 | 0.202 | 464 | 94 | 3566 | Standard |

The above data show that Inv-5 has comparable blue color and efficiency to the standard dopant. In addition, the stability is improved.

TABLE 5
Electroluminescence and stability data for Inv-6

| | Inv-6 | TBP | | | | Emission | | | |
|---|---|---|---|---|---|---|---|---|---|
| | Level | Level | Efficiency | | | λmax | Stability | T50 | |
| Example | (%) | (%) | (W/A) | CIEx | CIEy | (nm) | (%) | Extrapolated | Type |
| 34 | 0.5 | 0.0 | 0.045 | 0.153 | 0.200 | 460 | 85 | 2605 h | Inventive |
| 35 | 1.0 | 0.0 | 0.042 | 0.153 | 0.209 | 460 | 87 | 3322 h | Inventive |
| 36 | 1.5 | 0.0 | 0.040 | 0.154 | 0.223 | 464 | 88 | 2945 h | Inventive |
| 37 | 2.0 | 0.0 | 0.038 | 0.155 | 0.235 | 464 | 86 | 2873 h | Inventive |
| 38 | 0.0 | 1.0 | 0.040 | 0.147 | 0.199 | 464 | 85 | 2604 h | Standard |

The above data show that Inv-6 has comparable blue color and efficiency to the standard dopant. In addition, the stability is improved.

TABLE 6
lectroluminescence and stability data for Inv-7

| | Inv-7 | TBP | | | | Emission | | | |
|---|---|---|---|---|---|---|---|---|---|
| | Level | Level | Efficiency | | | λmax | Stability | T50 | |
| Example | (%) | (%) | (W/A) | CIEx | CIEy | (nm) | (%) | Extrapolated | Type |
| 39 | 1.5 | 0.0 | 0.051 | 0.147 | 0.227 | 464 | 82 | 3704 h | Inventive |
| 40 | 2.0 | 0.0 | 0.049 | 0.148 | 0.220 | 464 | 83 | 3034 h | Inventive |
| 41 | 3.0 | 0.0 | 0.043 | 0.150 | 0.237 | 464 | 83 | 4474 h | Inventive |
| 42 | 0.0 | 1.0 | 0.046 | 0.144 | 0.189 | 464 | 86 | 2300 h | Standard |

The above data show that Inv-7 has comparable blue color and efficiency to the standard dopant. In addition, the stability is improved.

TABLE 7
Electroluminescence and stability data for Inv-9a.

| | Inv-9a | TBP | | | | Emission | | | |
|---|---|---|---|---|---|---|---|---|---|
| | Level | Level | Efficiency | | | λmax | Stability | T50 | |
| Example | (%) | (%) | (W/A) | CIEx | CIEy | (nm) | (%) | Extrapolated | Type |
| 43 | 0.5 | 0.0 | 0.045 | 0.165 | 0.241 | 464 | 88 | 3352 h | Inventive |
| 44 | 1.0 | 0.0 | 0.044 | 0.170 | 0.267 | 464 | 90 | 4047 h | Inventive |
| 45 | 1.5 | 0.0 | 0.043 | 0.174 | 0.284 | 464 | 88 | 3973 h | Inventive |
| 46 | 2.0 | 0.0 | 0.041 | 0.176 | 0.291 | 464 | 88 | 4256 h | Inventive |
| 47 | 0.0 | 1.0 | 0.044 | 0.146 | 0.189 | 460 | 88 | 2878 h | Standard |

The above data show that Inv-9a has comparable blue color and efficiency to the standard dopant. In addition, the stability is improved.

TABLE 8
Electroluminescence and stability data for Inv-46.

| | Inv-46 | TBP | | | | Emission | | | |
|---|---|---|---|---|---|---|---|---|---|
| | Level | Level | Efficiency | | | λmax | Stability | T50 | |
| Example | (%) | (%) | (W/A) | CIEx | CIEy | (nm) | (%) | Extrapolated | Type |
| 48 | 1.0 | 0.0 | 0.047 | 0.153 | 0.231 | 468 | 88 | 3876 h | Inventive |
| 49 | 1.5 | 0.0 | 0.046 | 0.153 | 0.241 | 468 | 89 | 3820 h | Inventive |
| 50 | 2.0 | 0.0 | 0.044 | 0.154 | 0.250 | 468 | 90 | 4516 h | Inventive |
| 51 | 0.0 | 1.0 | 0.045 | 0.146 | 0.169 | 460 | 80 | 2254 h | Standard |

The above data show that Inv-46 has comparable blue color and efficiency to the standard dopant. In addition, the stability is improved.

TABLE 9
Electroluminescence and stability data for Inv-47.

| | Inv-47 | TBP | | | | Emission | | | |
|---|---|---|---|---|---|---|---|---|---|
| | Level | Level | Efficiency | | | λmax | Stability | T50 | |
| Example | (%) | (%) | (W/A) | CIEx | CIEy | (nm) | (%) | Extrapolated | Type |
| 52 | 1.0 | 0.0 | 0.052 | 0.149 | 0.220 | 464 | 82 | 2350 h | Inventive |
| 53 | 2.0 | 0.0 | 0.048 | 0.151 | 0.237 | 468 | 84 | 3440 h | Inventive |
| 54 | 4.0 | 0.0 | 0.041 | 0.154 | 0.268 | 468 | 83 | 3569 h | Inventive |
| 55 | 0.0 | 1.0 | 0.045 | 0.142 | 0.177 | 460 | 79 | 2356 h | Standard |

The above data show that Inv-47 has comparable blue color and efficiency to the standard dopant. In addition, the stability is improved.

The invention has been described in detail with particular reference to certain preferred embodiments thereof, but it will be understood that variations and modifications can be effected within the spirit and scope of the invention. The patents and other publications referred to herein are hereby incorporated by reference.

### PARTS LIST

101 Substrate
103 Anode
105 Hole Injecting layer (HIL)
107 Hole Transporting layer (HTL)
108 Exciton blocking layer (EBL)
109 Light Emitting layer (LEL)
110 Hole and/or Excition Blocking layer (HBL)
111 Electron Transporting layer (ETL)
113 Cathode
150 Voltage/Current Source
160 Conductors

1. An OLED device comprising a light-emitting layer containing a host and a light-emitting anthracene compound bearing a 10-ethynyl moiety as the predominant light-emitting compound in the layer.

2. The element of claim 1 wherein the 10-ethynyl moiety is substituted with a fused ring group or a para-substituted phenyl group.

3. The device of claim 2 wherein the 10-ethynyl moiety is substituted with a fused ring group.

4. The device of claim 2 wherein the 10-ethynyl moiety is substituted with a para-substituted phenyl group

5. The device of claim 1 wherein the 10-ethynyl anthracene light-emitting compound is present in an amount of less than 10 vol. % of the light-emitting layer.

6. The device of claim 1 wherein the 10-ethynyl anthracene light-emitting compound is present in an amount of less than 5 vol. % of the light-emitting layer.

7. The device of claim 1 wherein the 10-ethynyl anthracene light-emitting compound is present in an amount of at least 0.5 and less than 3 vol. % of the light-emitting layer.

8. The device of claim 1 wherein the 10-ethynyl anthracene light-emitting compound is the only light emitting compound in the layer.

9. The device of claim 1 wherein the 10-ethynyl anthracene light-emitting compound is represented by Formula (1): 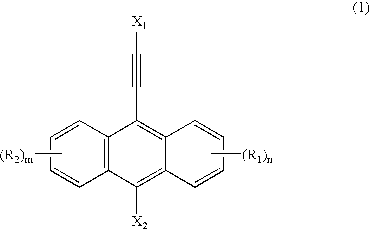
wherein
X₁ is an alkyl, silyl, or aromatic group;
X₂ selected from hydrogen or a substituent group; and
each R₁ and R₂ is an individually selected substituent where each of m and n is independently 0 to 4.

10. The device of claim 9 wherein X₁ is a carbocyclic group.

11. The device of claim 10 wherein the carbocyclic group is a phenyl or fused ring group.

12. The device of claim 10 wherein the carbocyclic group is a phenyl group.

13. The device of claim 12 wherein the carbocyclic group is a para-substituted phenyl group.

14. The device of claim 12 wherein the carbocyclic group is a fused ring group.

15. The device of claim 9 wherein X₂ is an aromatic group.

16. The device of claim 9 wherein X₂ is a phenyl or naphthyl group.

17. The device of claim 1 suitable for emitting white light.

18. An area lighting device comprising the device of claim 1.

19. The device of claim 1 wherein the light emitter has a wavelength of maximum emission in the range of 400-430 nm.

20. The device of claim 1 wherein the light emitting compound has a wavelength of maximum emission in the range of 450-490 nm.

21. The device of claim 1 wherein the light-emitting compound is part of a polymer.

22. A display device comprising the OLED device of claim 1.

23. A process for producing light comprising applying a voltage across the electrodes to the device of claim 1.
